(19) United States
(12) Patent Application Publication
(10) Pub. No.: US 2025/0140624 A1
(43) Pub. Date: May 1, 2025

(54) PACKAGES WITH ISOLATED DIES

(71) Applicant: TEXAS INSTRUMENTS INCORPORATED, Dallas, TX (US)

(72) Inventors: Hau NGUYEN, San Jose, CA (US); Vivek ARORA, San Jose, CA (US); Patrick Francis THOMPSON, Allen, TX (US); Masamitsu MATSUURA, Beppu-Shi Oita-Ken (JP); Daiki KOMATSU, Beppu-Shi Oita-Ken (JP)

(21) Appl. No.: 18/496,667

(22) Filed: Oct. 27, 2023

(51) Int. Cl. H01L 23/31; H01L 21/56; H01L 21/78; H01L 23/00; H01L 23/29; H01L 25/065

(52) U.S. Cl. CPC H01L 23/3135; H01L 21/561; H01L 21/568; H01L 21/78; H01L 23/293; H01L 24/04; H01L 24/05; H01L 24/13; H01L 24/20; H01L 25/0655; H10D 1/692; H01L 23/291; H01L 2224/0401; H01L 2224/04105; H01L 2224/05082; H01L 2224/05147; H01L 2224/05573; H01L 2224/13014; H01L 2224/2105; H01L 2224/211

(57) ABSTRACT

A wafer chip scale package (WCSP) comprises first and second dies in differing voltage domains and an isolation material between the first and second dies and contacting multiple surfaces of each of the first and second dies. The package also comprises a first resin material contacting multiple surfaces of the isolation material, with the isolation material between the resin material and the first and second dies. The package also comprises a fiberglass material contacting a surface of the resin material and a second resin material contacting a surface of the fiberglass material. The package also comprises first and second conductive structures coupled to the first and second dies, respectively. The package also includes a passivation material contacting the first and second dies and the first and second conductive structures.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. The singulated dies may be coupled to conductive terminals and covered by a mold compound to form a package.

### SUMMARY

In examples, a wafer chip scale package (WCSP) comprises first and second dies in differing voltage domains and an isolation material between the first and second dies and contacting multiple surfaces of each of the first and second dies. The package also comprises a first resin material contacting multiple surfaces of the isolation material, with the isolation material between the resin material and the first and second dies. The package also comprises a fiberglass material contacting a surface of the resin material and a second resin material contacting a surface of the fiberglass material. The package also comprises first and second conductive structures coupled to the first and second dies, respectively. The package also includes a passivation material contacting the first and second dies and the first and second conductive structures.

In examples, a method for manufacturing a wafer chip scale package (WCSP) comprises backgrinding a semiconductor wafer; coupling the wafer to an expandable dicing tape; patterning a photoresist on a non-device side of the wafer; etching the wafer using the photoresist to produce first and second dies separated by a gap; filling the gap with an isolation material; covering multiple surfaces of the first and second dies with the isolation material; and performing a sawing process to produce a WCSP including the first and second dies.

### BRIEF DESCRIPTION OF THE DRAWINGS

FIG. 1 is a block diagram of an electronic device containing a package with isolated semiconductor dies, in accordance with various examples.

FIG. 2A is a profile, cross-sectional view of a package with isolated semiconductor dies, in accordance with various examples.

FIG. 2B is a top-down, see-through view of a package with isolated semiconductor dies, in accordance with various examples.

FIG. 2C is a perspective, see-through view of a package with isolated semiconductor dies, in accordance with various examples.

FIG. 3A is a profile, cross-sectional view of a package with isolated semiconductor dies, in accordance with various examples.

FIG. 3B is a top-down, see-through view of a package with isolated semiconductor dies, in accordance with various examples.

FIG. 3C is a perspective, see-through view of a package with isolated semiconductor dies, in accordance with various examples.

FIG. 4 is a flow diagram of a method for manufacturing a package with isolated semiconductor dies, in accordance with various examples.

FIGS. 5A1-5O3 are a process flow for manufacturing a package with isolated semiconductor dies, in accordance with various examples.

FIGS. 6A1-6O3 are a process flow for manufacturing a package with isolated semiconductor dies, in accordance with various examples.

### DETAILED DESCRIPTION

Many packages contain semiconductor dies with high and low voltage domains. Trenches are sometimes positioned in between these differing voltage domains to prevent current leakage between the domains, but the trenches are frequently ineffective. For example, current may leak from the high voltage domain to the low voltage domain through the die, such as following an electric shock to the package. Such current leakage can be particularly problematic in certain types of packages, such as wafer chip scale packages deployed in high voltage applications. Current leakage can compromise the functional and mechanical integrity of the package.

This disclosure describes various examples of a package that mitigates the technical challenges described above. Specifically, the package includes multiple semiconductor dies (e.g., two or more dies) in separate voltage domains and an isolation material, such as parylene, positioned between the dies. The isolation material encapsulates each of the multiple dies by contacting each such die on multiple lateral surfaces of the die and on the bottom surface (i.e., non-device side) of the die. The package further includes supporting structures that provide the package with rigidity and mechanical strength, such as a first asymmetric pre-preg (APP) resin material contacting the isolation material, an APP fiberglass material contacting the first APP resin material, and a second APP resin material contacting the APP fiberglass material. The isolation material encapsulating the multiple semiconductor dies eliminates any electrical pathways along which leakage current could flow between the dies, thus mitigates the challenges described above. Various examples of the package are now described with reference to the drawings.

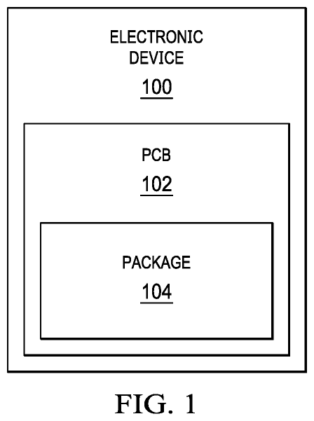

FIG. 1 is a block diagram of an electronic device 100 containing a package with isolated semiconductor dies, in accordance with various examples. The electronic device 100 may be any suitable type of device, such as a computer (e.g., a laptop, desktop, notebook), a smartphone, a household appliance, an entertainment device (e.g., musical entertainment, video entertainment), an automobile, an aircraft, a spacecraft, etc. The electronic device 100 includes a printed circuit board (PCB) 102. A package 104 is coupled to the PCB 102. Various examples of the package 104 are described below.

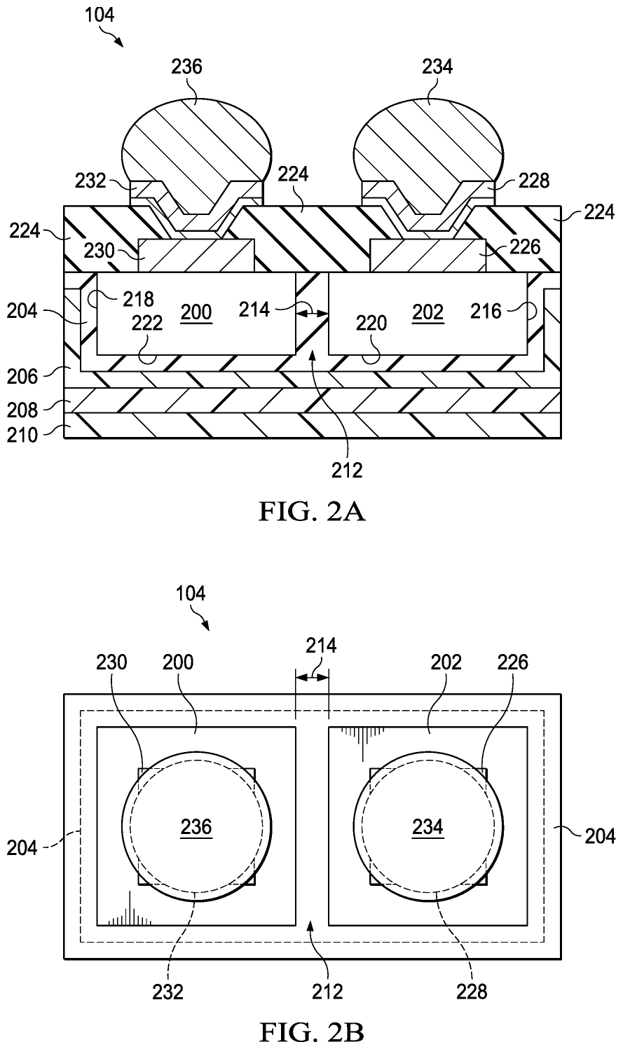

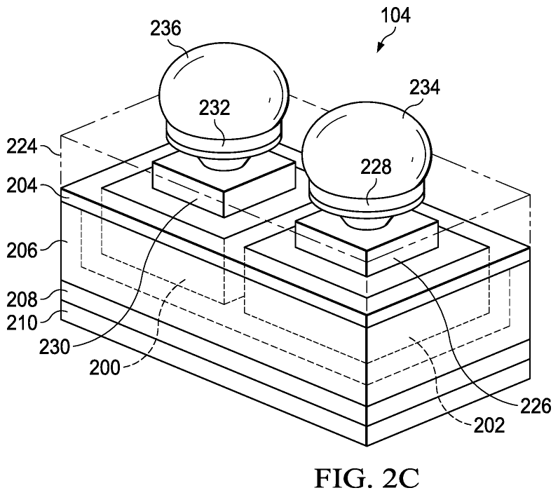

FIG. 2A is a profile, cross-sectional view of a package 104 with isolated semiconductor dies, in accordance with various examples. In examples, the package 104 is a wafer chip scale package (WCSP). The example package 104 includes semiconductor dies 200, 202. In examples, the die 200 is considered to be in a low-voltage domain, and the die 202 is considered to be in a high-voltage domain. For example, the die 200 may be coupled to a ground node, and the die 202 may be coupled to a voltage supply (also referred to as a voltage rail). However, in some examples, the die 200 may be considered to be in a high-voltage domain, and the die 202 may be considered to be in a low-voltage domain.

Each of the dies 200, 202 is encapsulated by an isolation material 204, such as parylene. The isolation material 204 encapsulates the die 200 by contacting the die 200 on all lateral surfaces 218 of the die 200 and on a bottom surface 222 of the die 200. The isolation material 204 may cover the entirety of each of the four lateral surfaces 218 and the entirety of the bottom surface 222. The isolation material 204 encapsulates the die 202 by contacting the die 202 on all (e.g., four) lateral surfaces 216 of the die 202 and on a bottom surface 220 of the die 202. The isolation material 204 may cover the entirety of each of the four lateral surfaces 216 of the die 202 and the entirety of the bottom surface 220. A portion 212 of the isolation material 204 is between the dies 200, 202 and has a thickness 214 ranging between 2 microns and 50 microns, with a thickness below this range being disadvantageous because it results in adequate isolation, and with a thickness above this range being disadvantageous because it results in unacceptably large package volume and cost. Top surfaces of the dies 200, 202, which oppose the bottom surfaces 222, 220, respectively, are not covered by the isolation material 204, or are only minimally covered by the isolation material 204. By encapsulating the dies 200, 202 with the isolation material 204 in this manner, leakage current that would otherwise flow between the dies 200, 202, which are in differing voltage domains, is eliminated.

Still referring to FIG. 2A, an asymmetric pre-preg (APP) material 206, such as a resin material, covers lateral and bottom surfaces of the isolation material 204, as shown. The APP material 206 functions to support the substrate handling system through downstream processes, such as wafer bump and wafer probe. The APP material 206 has a thickness ranging from 1 micron to 200 microns, with a thickness below this range being disadvantageous because it is incompatible with process tolerances, and with a thickness above this range being disadvantageous because of the unacceptably high cost and space occupied.

Further, an APP material 208, such as fiberglass, contacts the APP material 206 and functions to provide mechanical support and rigidity to the package 104. Accordingly, the fiberglass APP material 208 has a tensile modulus (i.e., a measure of rigidity) ranging from 1 gigapascals (GPa) to 30 GPa, with a tensile modulus below this range being disadvantageous because it causes substrate shagging and warpage, and with a tensile modulus above this range being disadvantageous because it causes substrate warpage. The APP material 208 has a thickness ranging from 10 microns to 100 microns, with a thickness below this range being disadvantageous because it causes substrate weakness and shagging, and with a thickness above this range being disadvantageous because it causes substrate warpage and unacceptably increases cost.

Furthermore, an APP material 210, such as a resin material, contacts the APP material 208 and functions to provide additional mechanical support and a surface for markings (e.g., specific trademarks, model numbers, lot numbers, etc.). The APP material 210 has a thickness ranging from 10 microns to 150 microns, with a thickness below this range being disadvantageous because it results in improper marking, and with a thickness above this range being disadvantageous because it unacceptably increases cost.

Still referring to FIG. 2A, metal contact pads 226, 230 contact top surfaces of the dies 202, 200, respectively. The metal contact pad 226 is coupled to an under bump metallization (UBM) 228, and the metal contact pad 230 is coupled to a UBM 232. The UBM 228 is coupled to a solder bump 234, and the UBM 232 is coupled to a solder bump 236. The metal contact pad 226 and the UBM 228 may collectively be referred to herein as a conductive structure. The metal contact pad 230 and the UBM 232 may collectively be referred to herein as a conductive structure. A passivation layer 224 covers the metal contact pads 226, 230.

FIG. 2B is a top-down, see-through view of the package 104 with isolated semiconductor dies, in accordance with various examples. FIG. 2C is a perspective, see-through view of the package 104 with isolated semiconductor dies, in accordance with various examples.

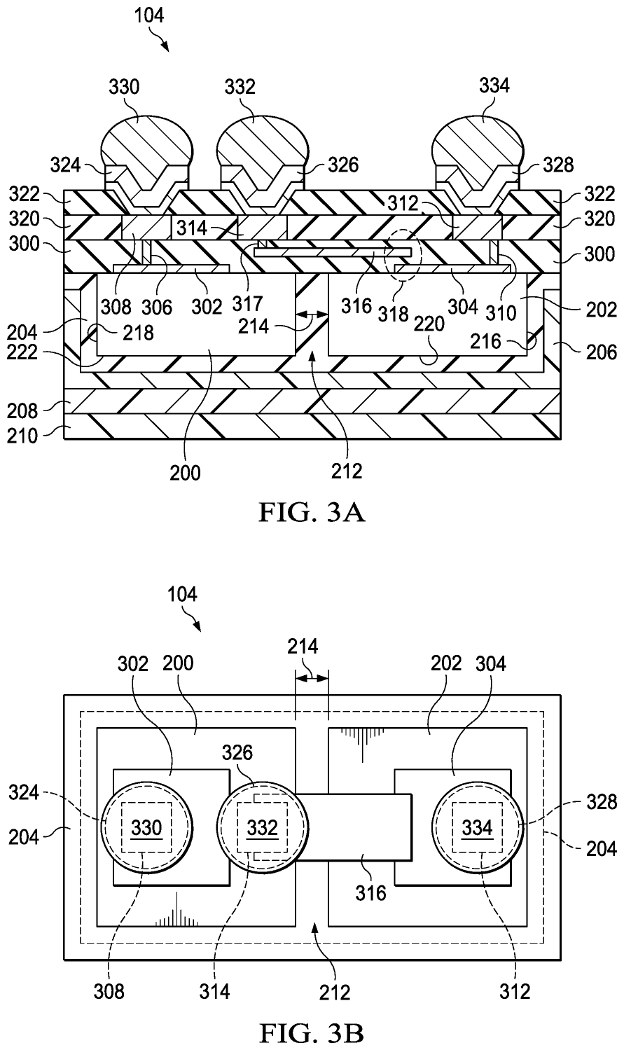

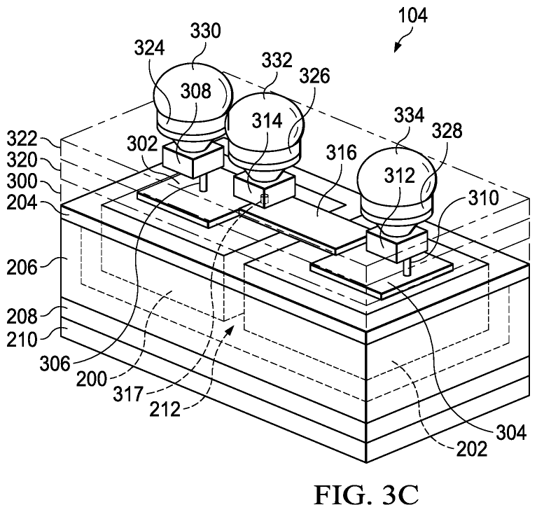

FIG. 3A is a profile, cross-sectional view of a package 104 with isolated semiconductor dies, in accordance with various examples. The package 104 of FIG. 3A differs from the package 104 of FIG. 2A, but both packages 104 of FIGS. 2A and 3A are examples of the package 104 shown in FIG. 1. The package 104 of FIG. 3A includes the dies 200, 202, the isolation material 204, and the APP materials 206, 208, and 210, each of which has been described above and thus is not described again here. The device side of the die 200 includes a metal trace 302, and the device side of the die 202 includes a metal trace 304. The thicknesses of the metal traces 302, 304 are exaggerated in the drawings to improve visibility. A via 306 couples the metal trace 302 to a metal contact pad 308. A via 310 couples the metal trace 304 to a metal contact pad 312. An oxide layer 300 covers the metal traces 302, 304 and the vias 306, 310. The oxide layer 300 also includes a metal layer 316 that is coupled to a metal contact pad 314 by way of a via 317. A passivation layer 320 covers the metal contact pads 308, 312, and 314. A polyimide layer 322 covers UBMs 324, 326, and 328, which are coupled to metal contact pads 308, 314, and 312, respectively. Solder bumps 330, 332, and 334 are coupled to UBMs 324, 326, and 328, respectively.

In examples, the package 104 may operate in multiple domains. For example, die 200 may operate in a first voltage domain, and die 202 may operate in a second voltage domain. Metal contact pad 308 may be a first terminal, and metal contact pad 312 may be a second terminal. Metal contact pad 314 may be a third terminal. The metal layer 316 may be located proximal to, but not directly coupled to, the metal trace 304. Consequently, the metal layer 316 and the metal trace 304 may be capacitively coupled at the area indicated by numeral 318.

FIG. 3B is a top-down, see-through view of the package 104 of FIG. 3A, in accordance with various examples. FIG. 3C is a perspective, see-through view of the package 104 of FIG. 3A, in accordance with various examples.

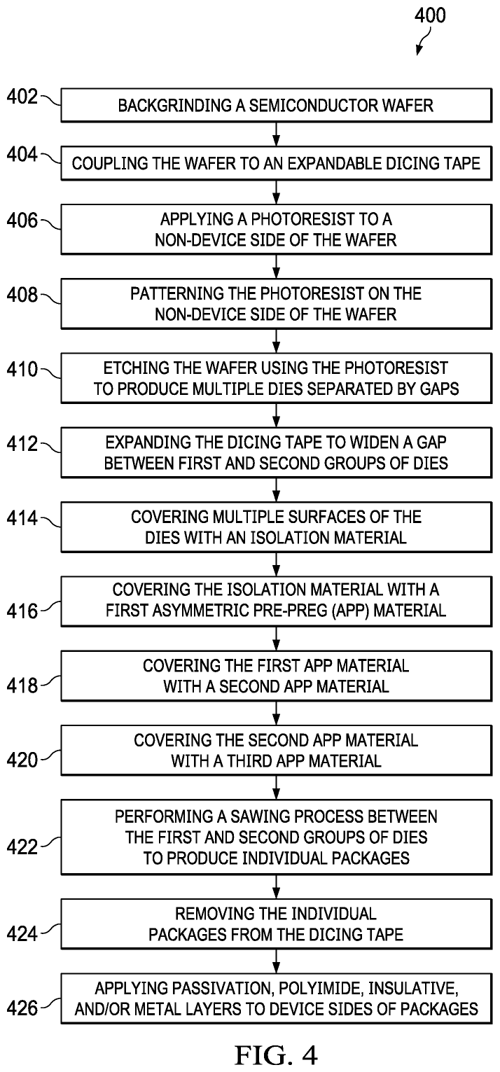

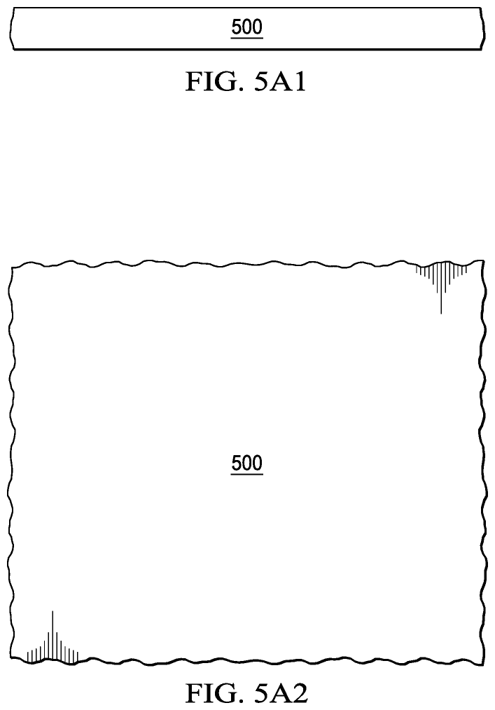

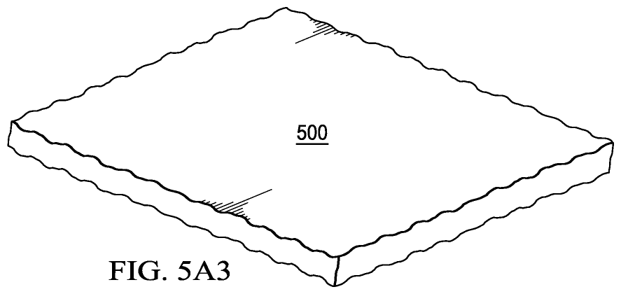

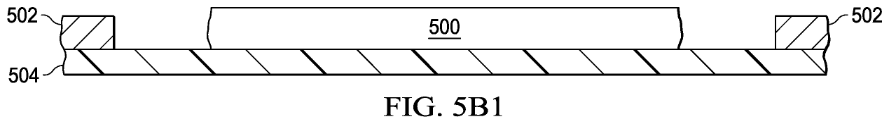

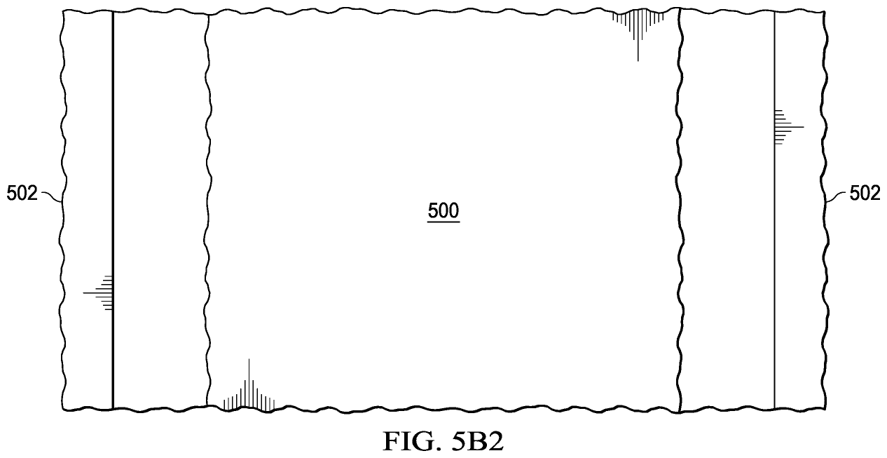

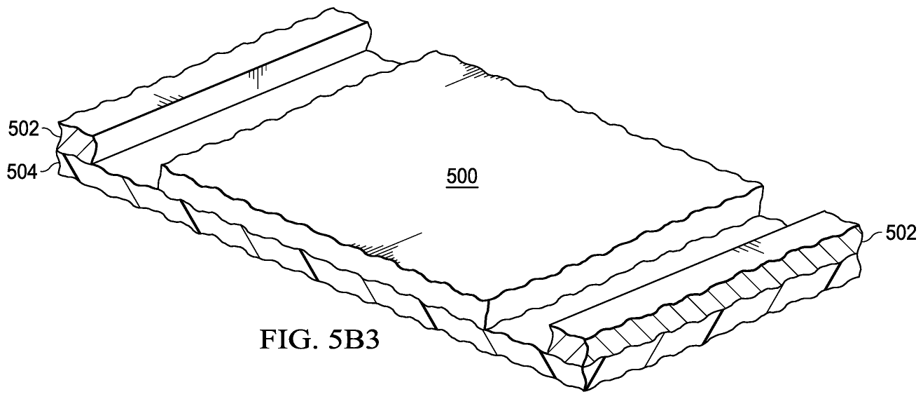

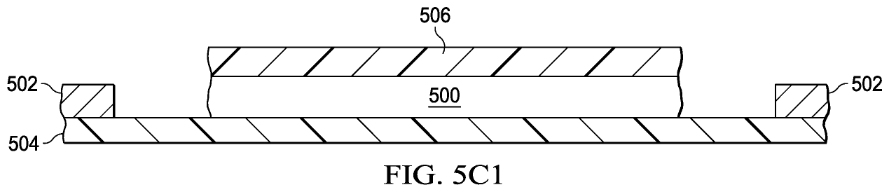

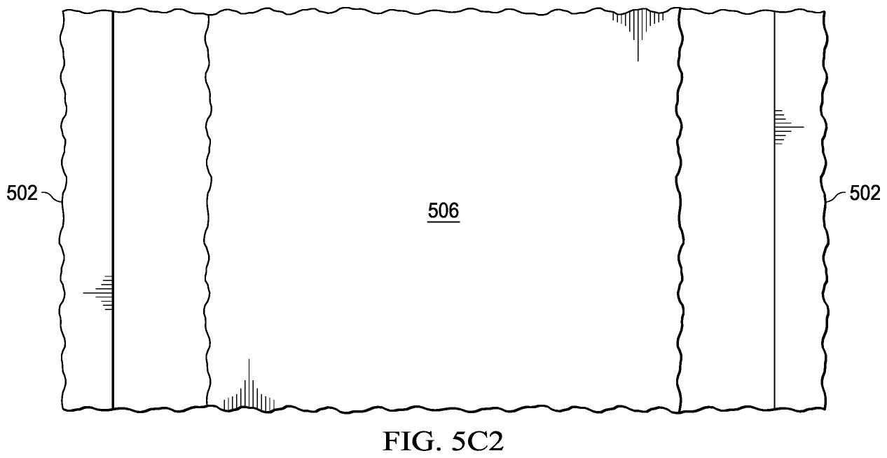

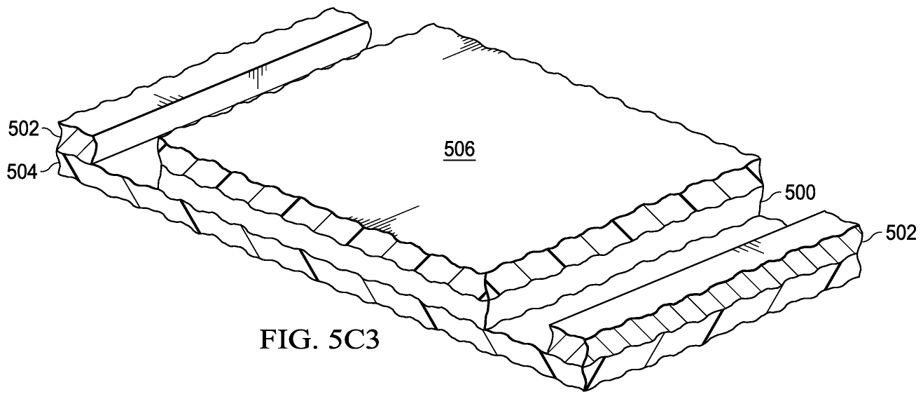

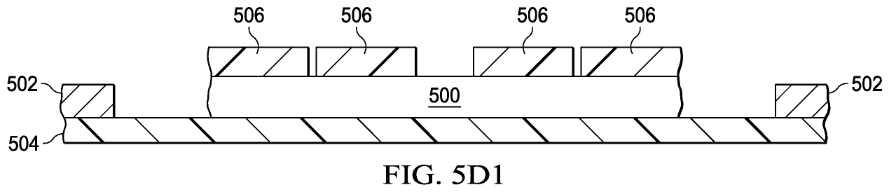

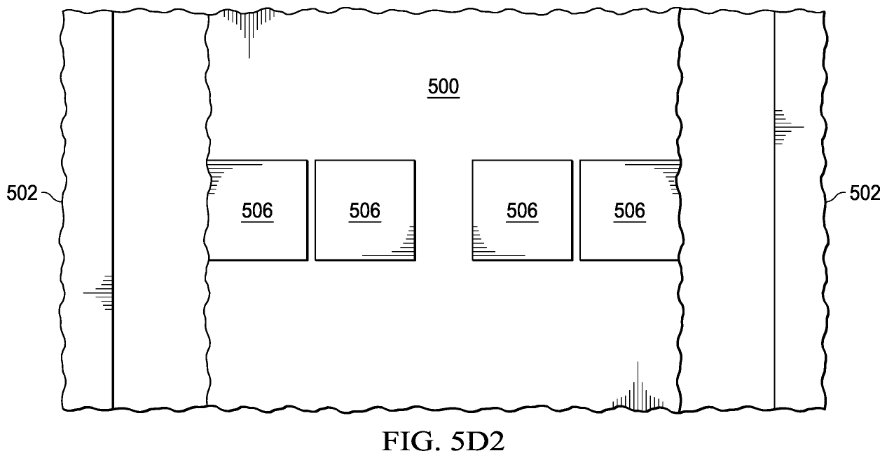

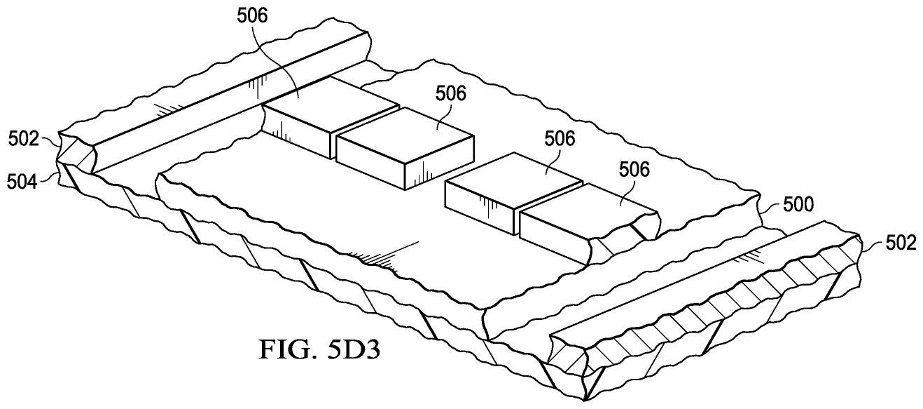

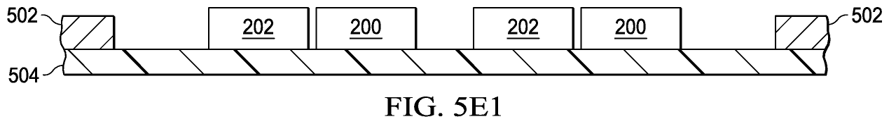

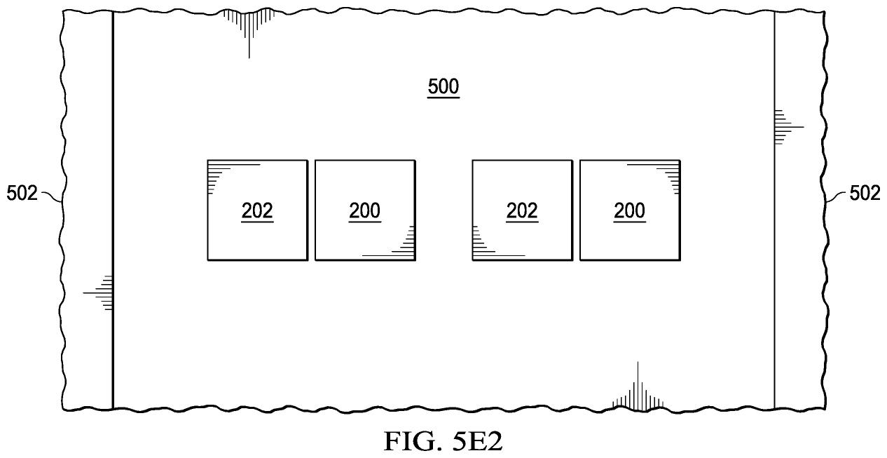

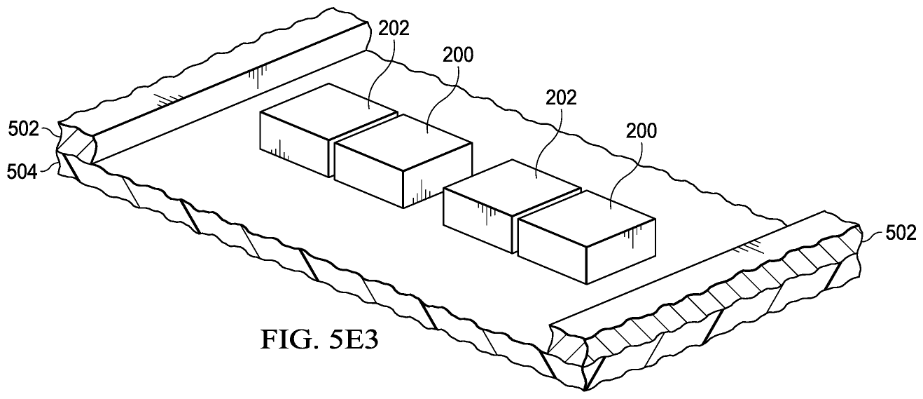

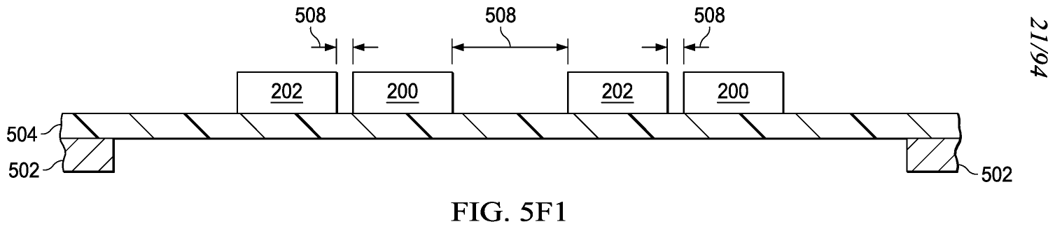

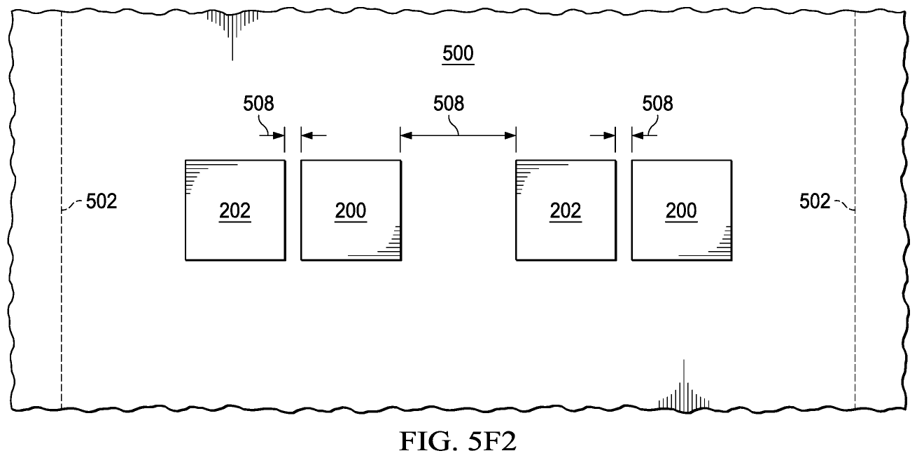

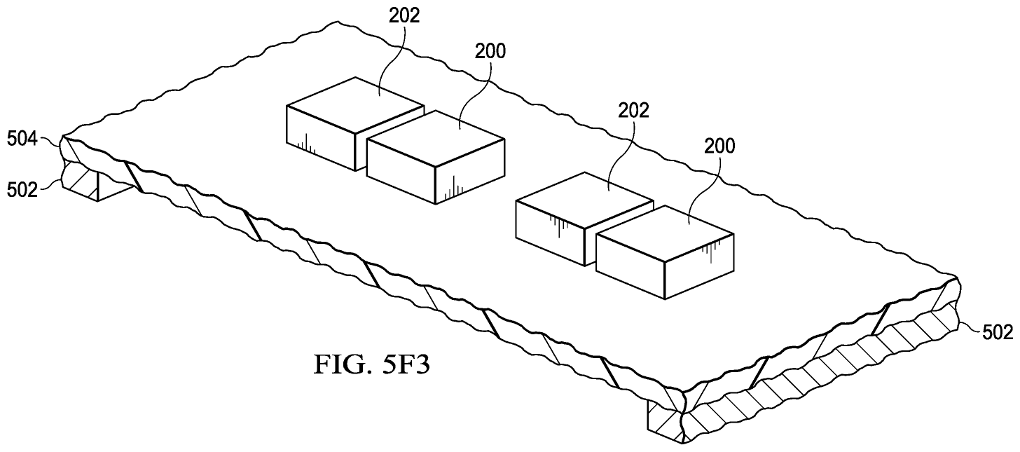

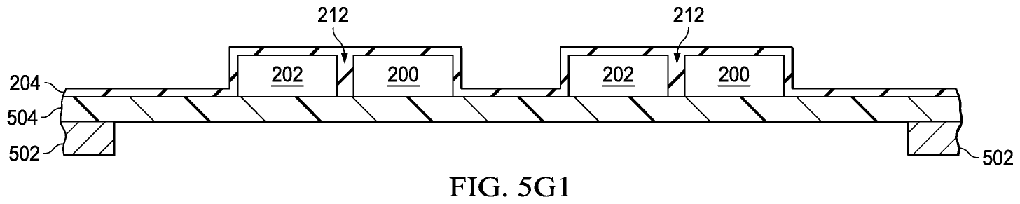

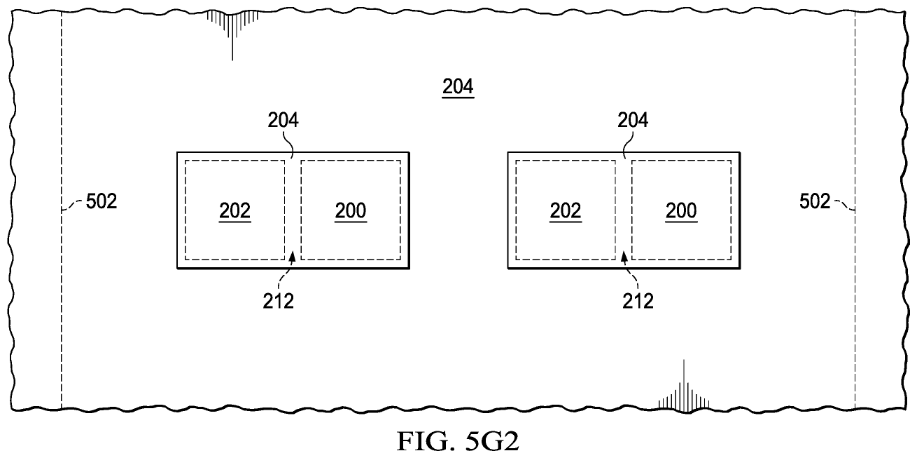

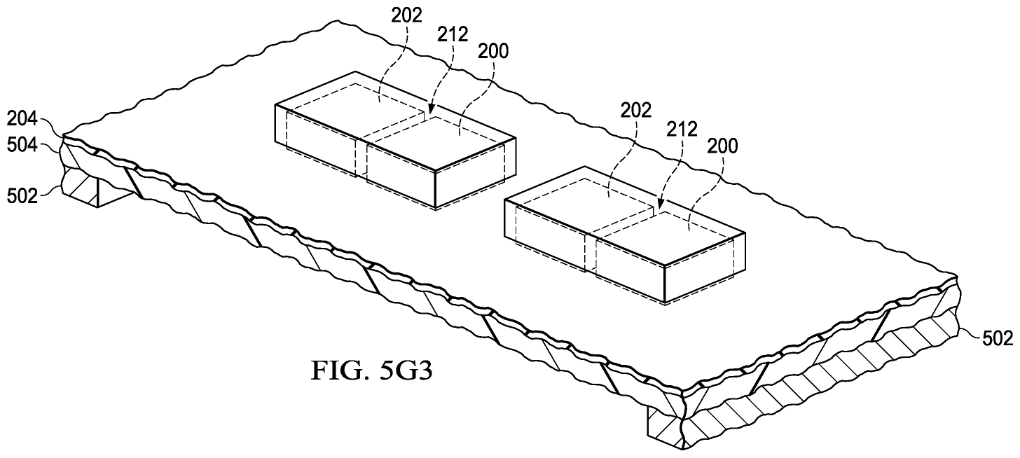

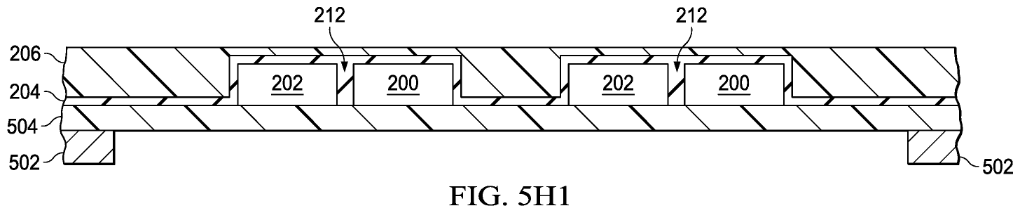

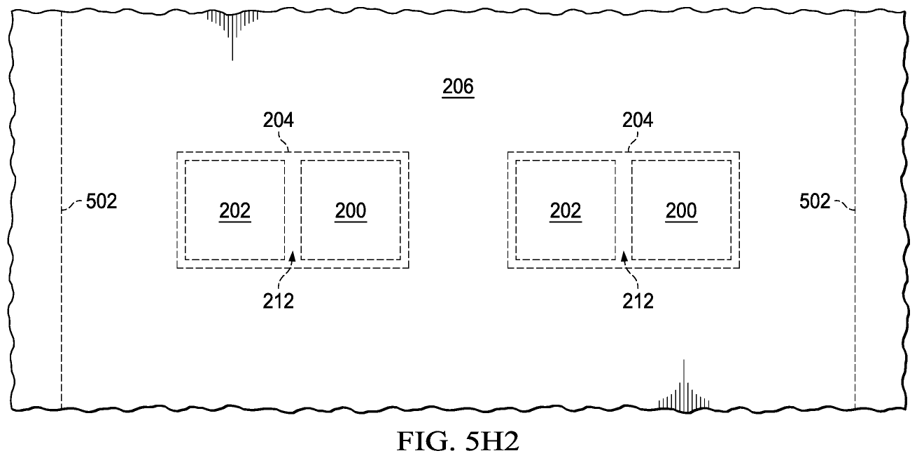

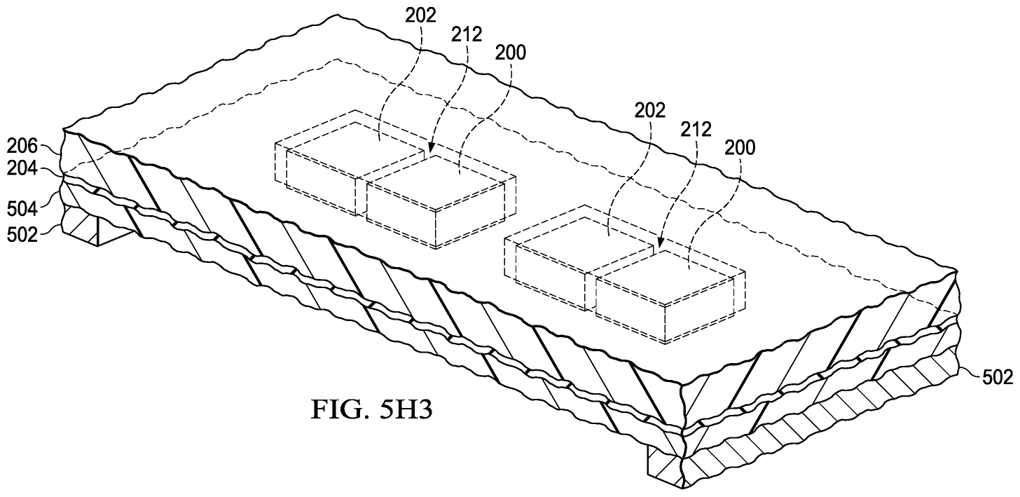

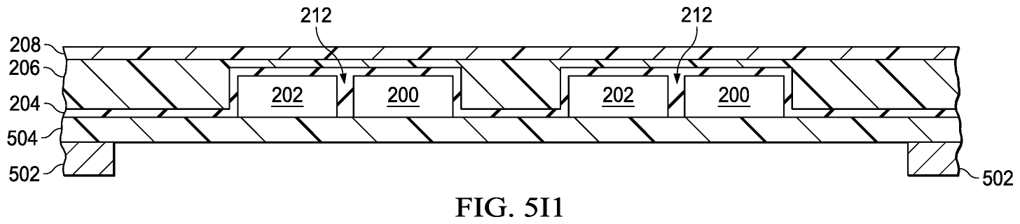

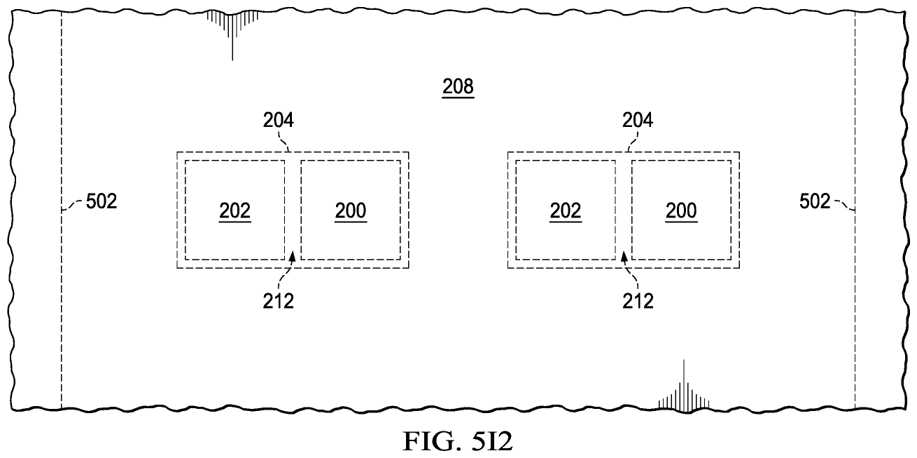

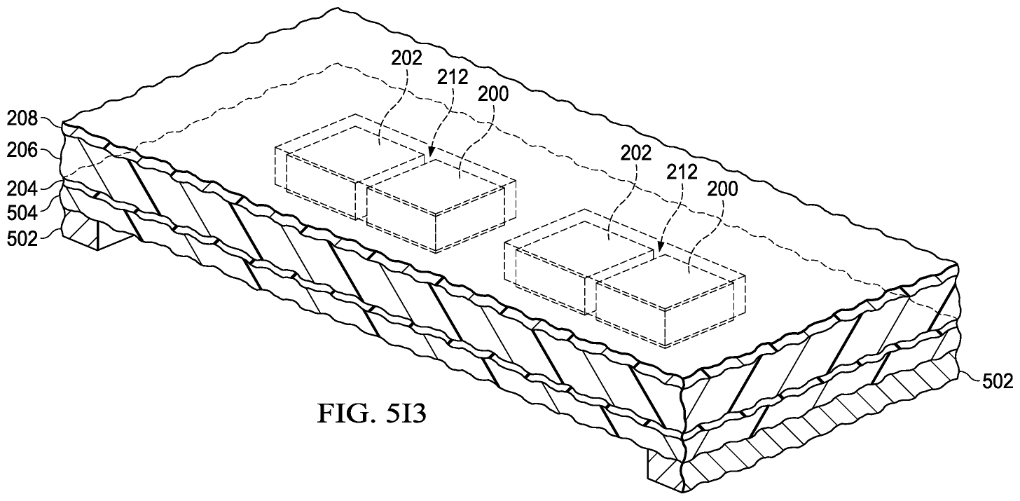

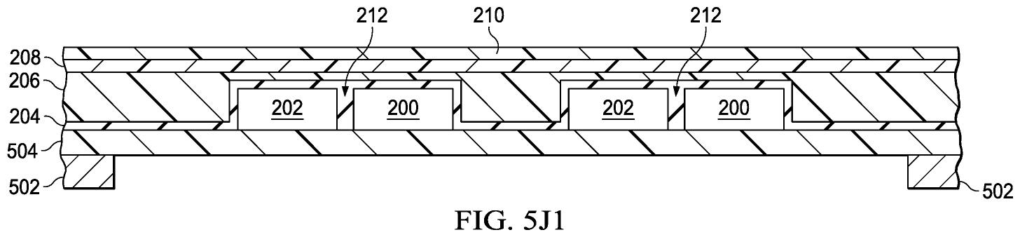

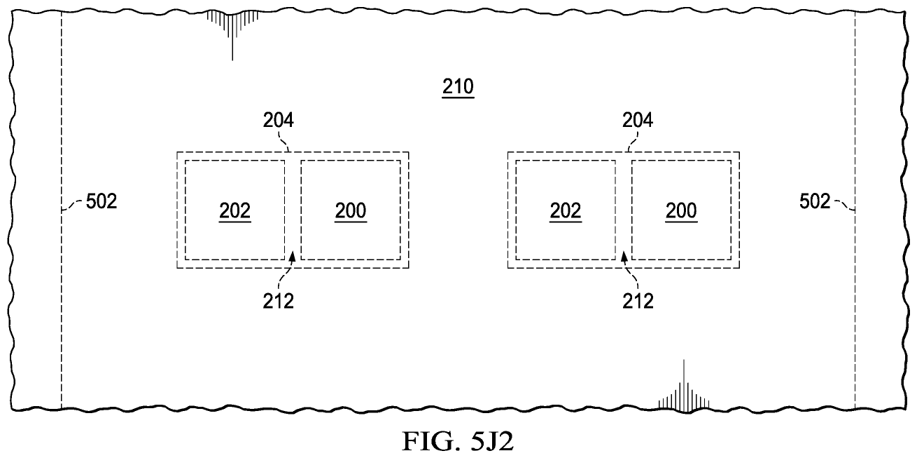

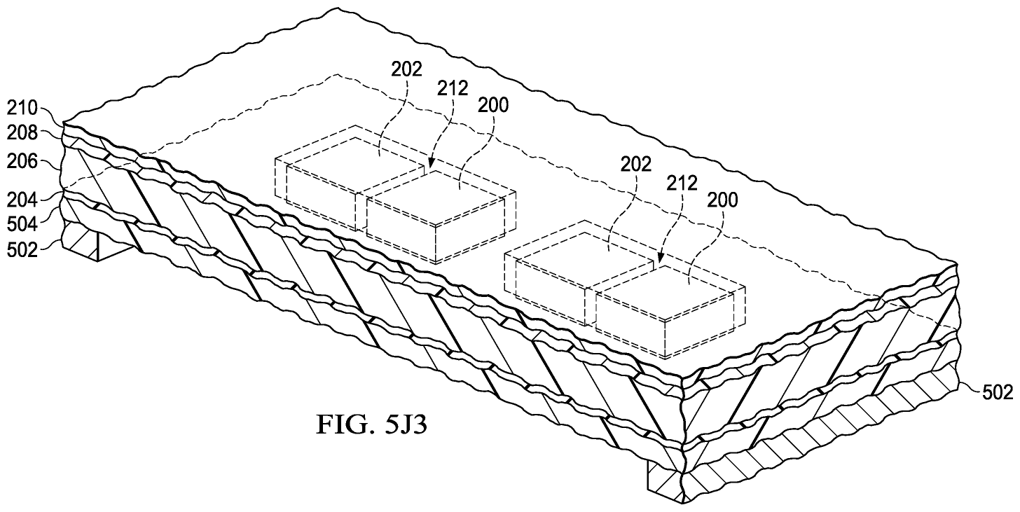

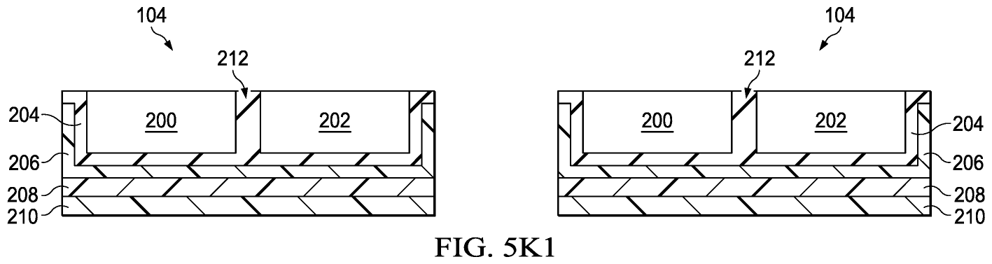

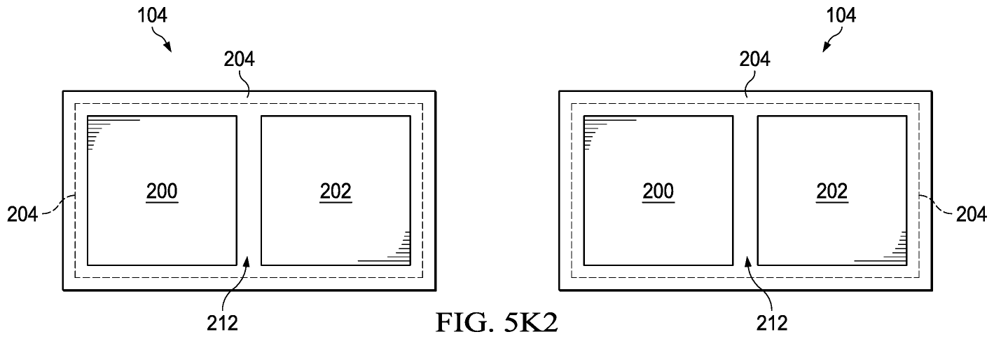

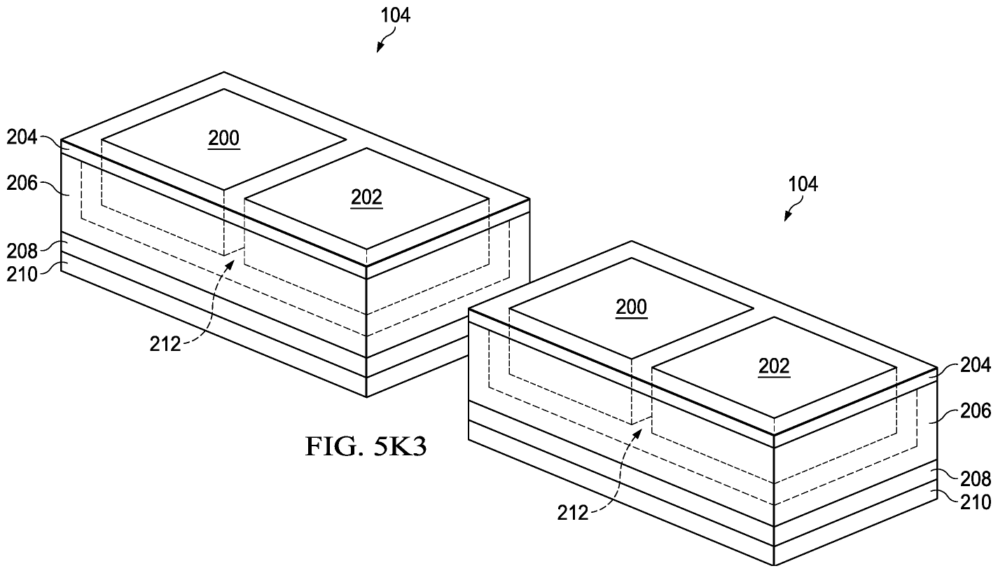

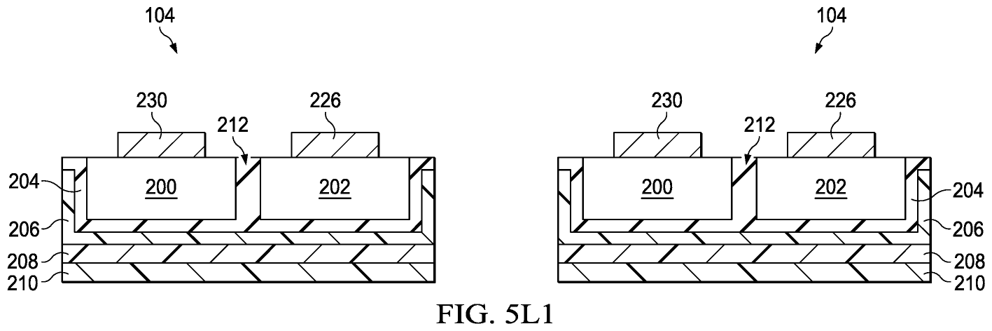

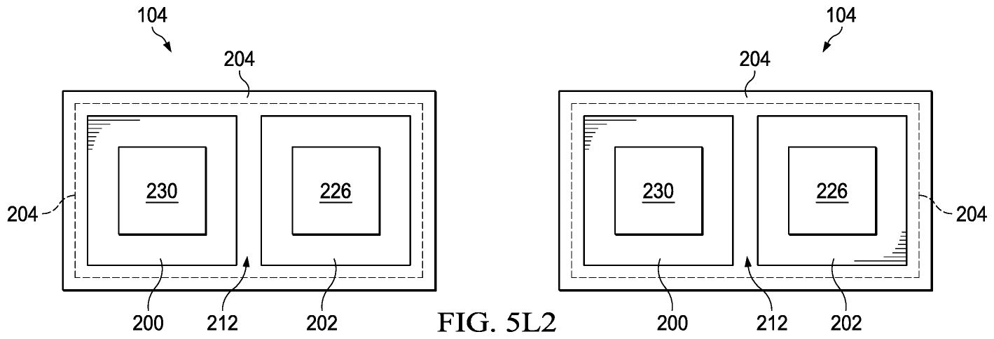

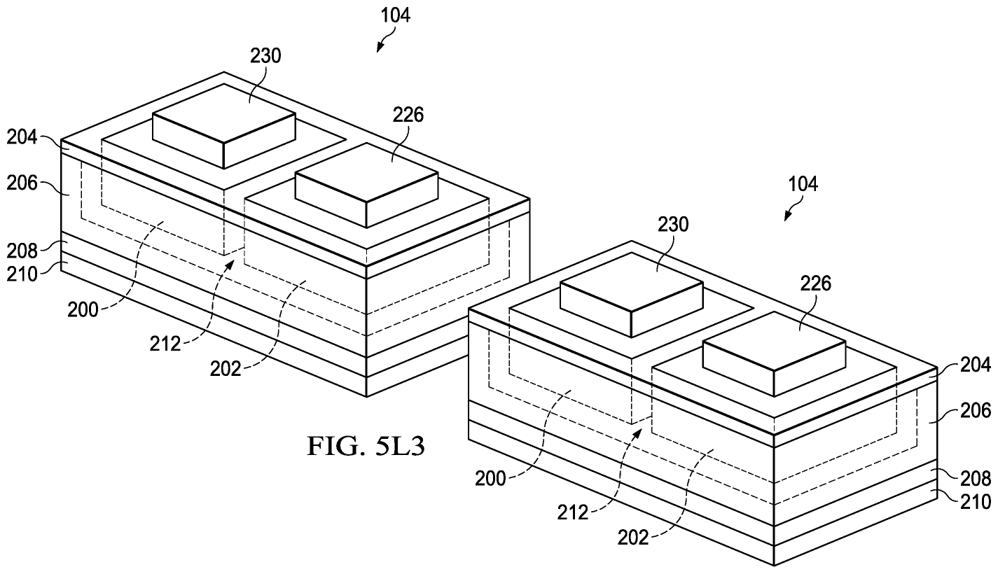

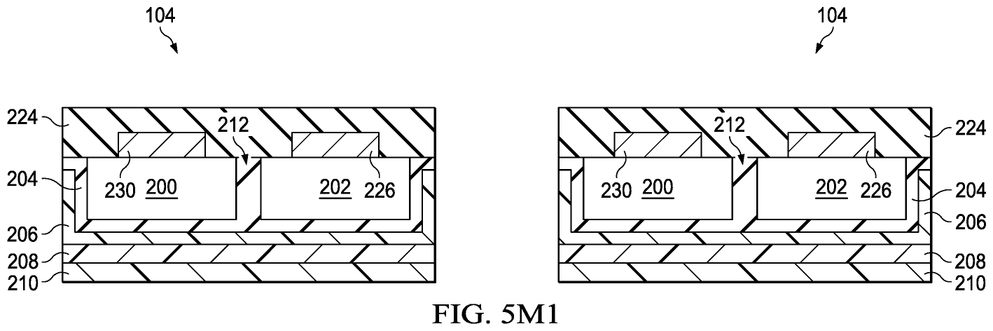

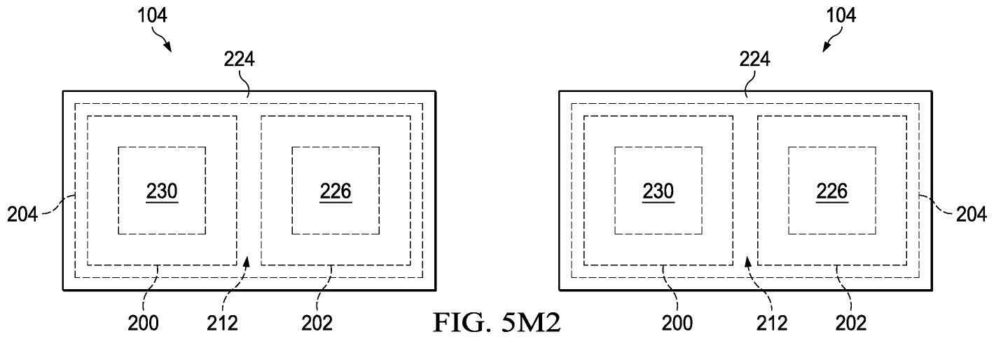

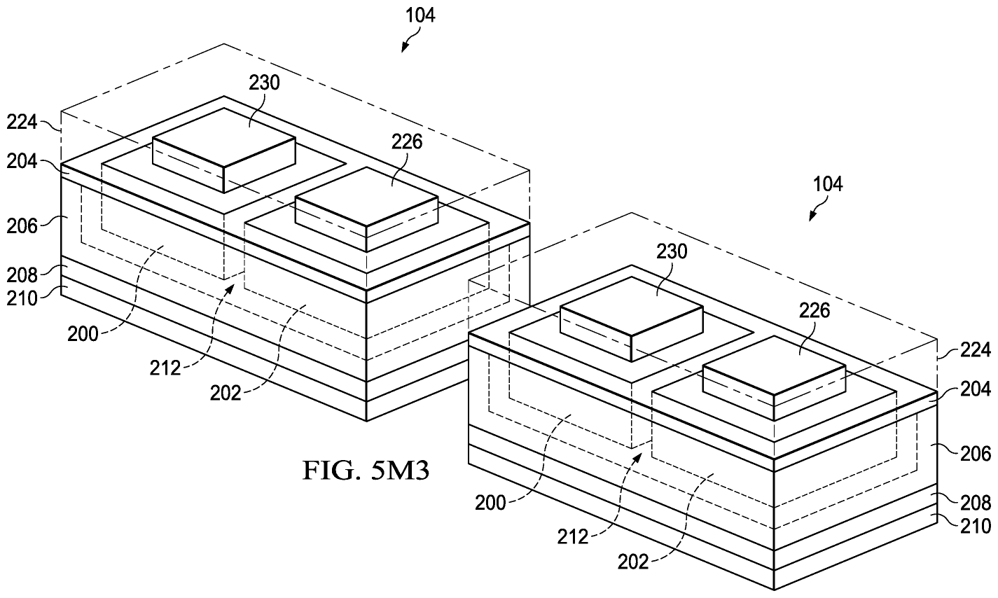

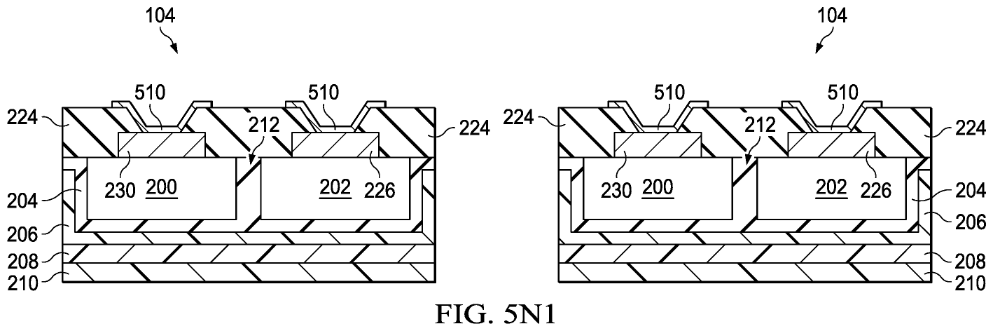

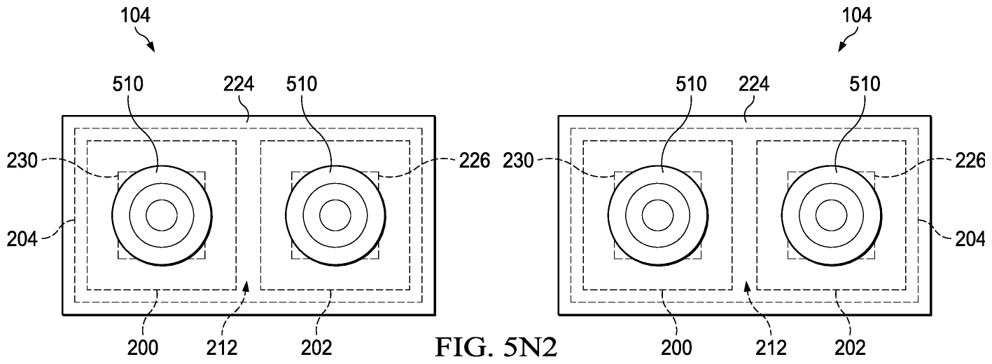

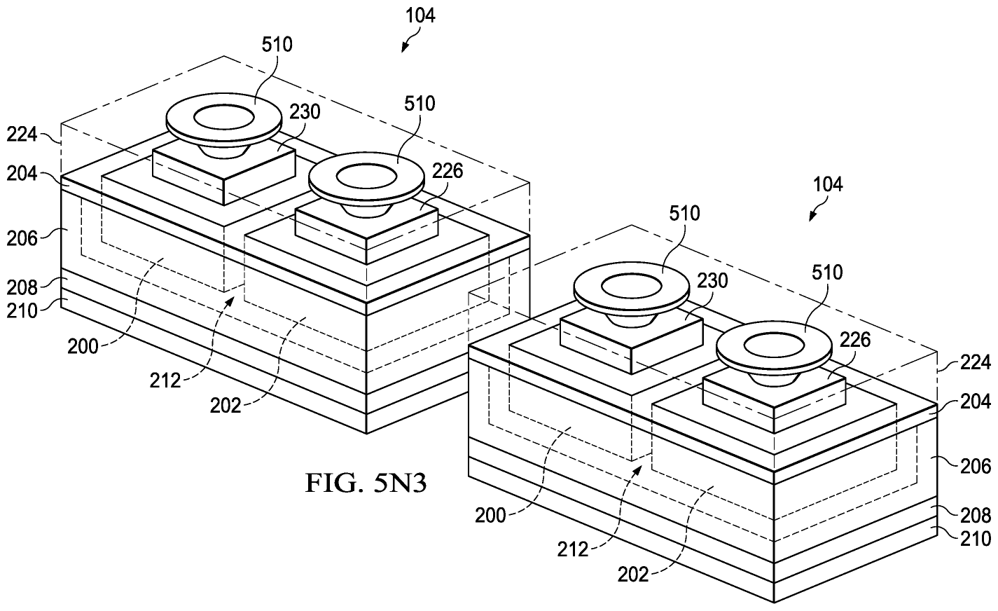

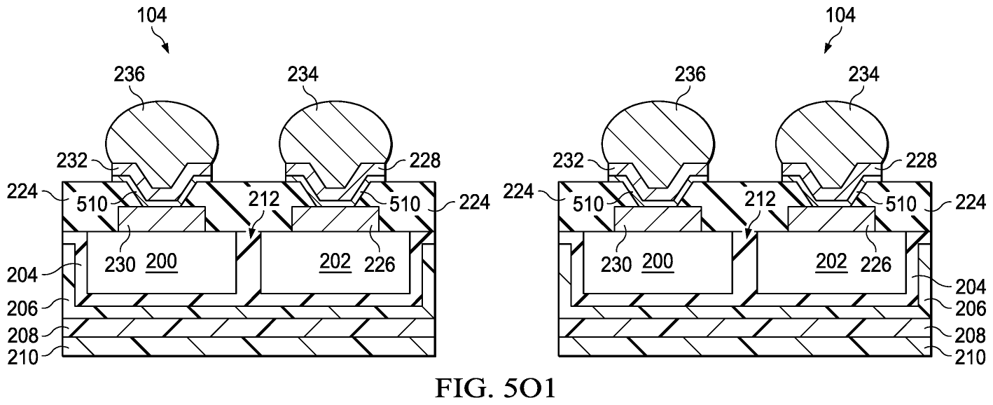

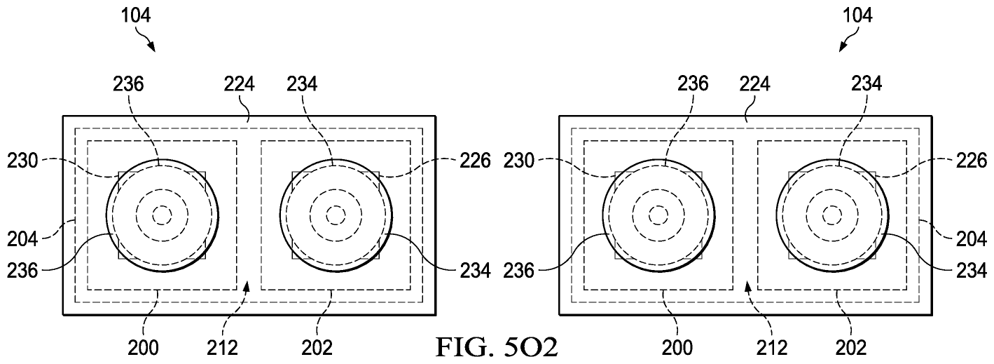

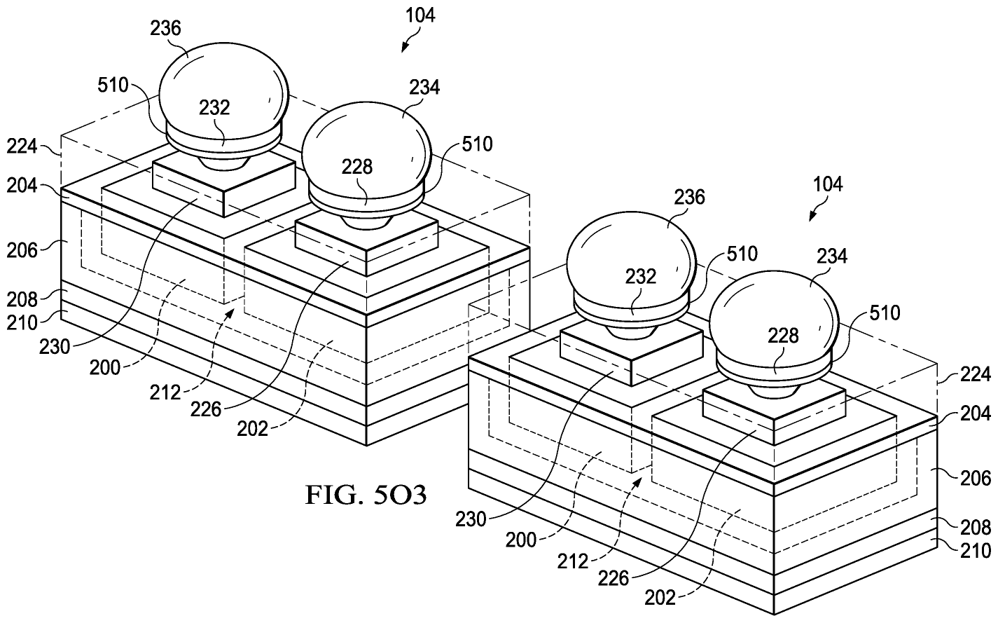

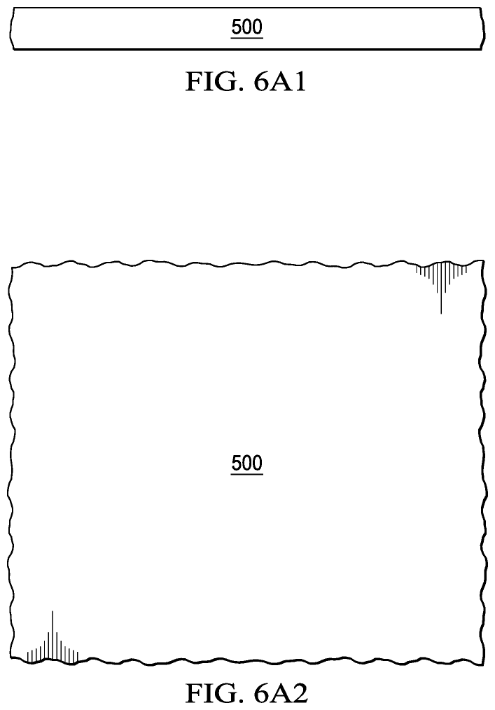

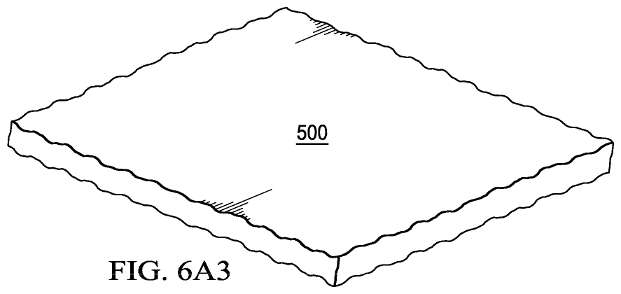

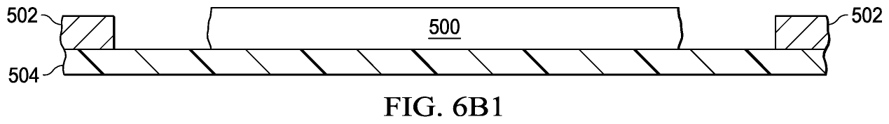

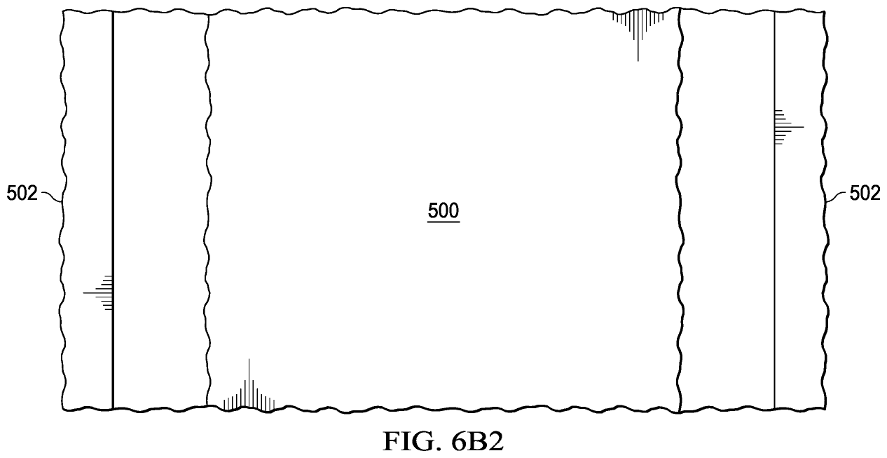

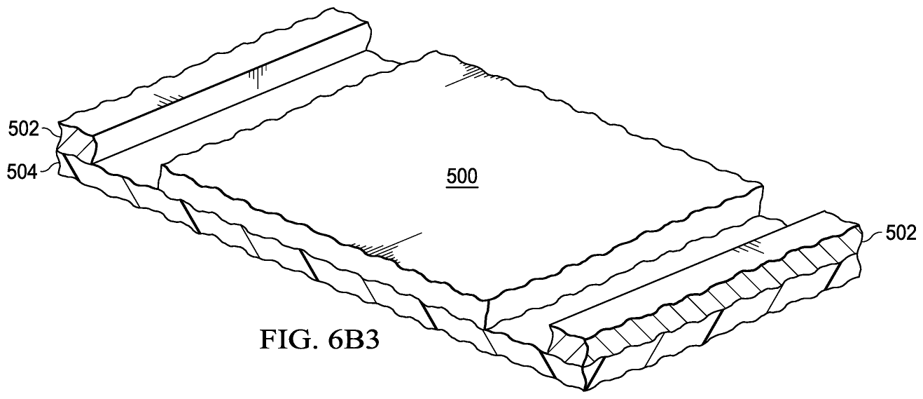

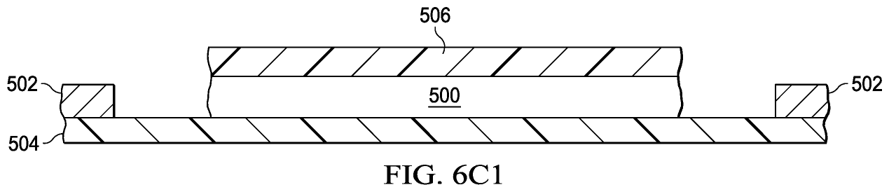

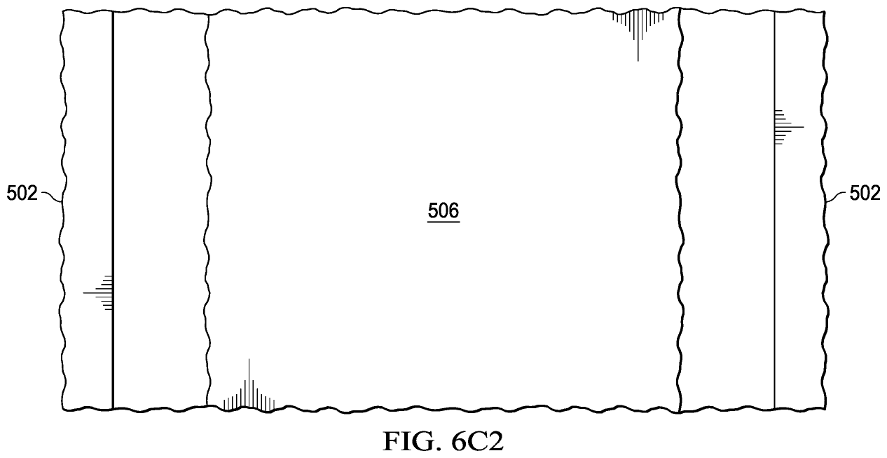

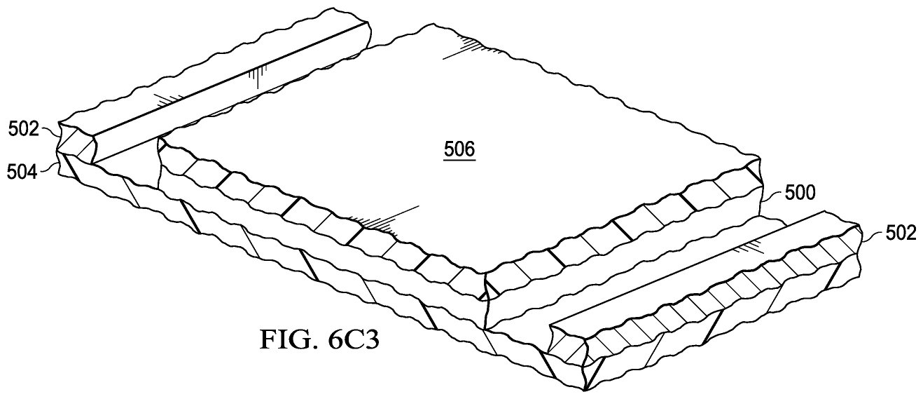

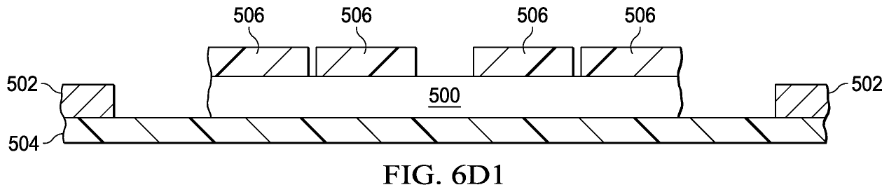

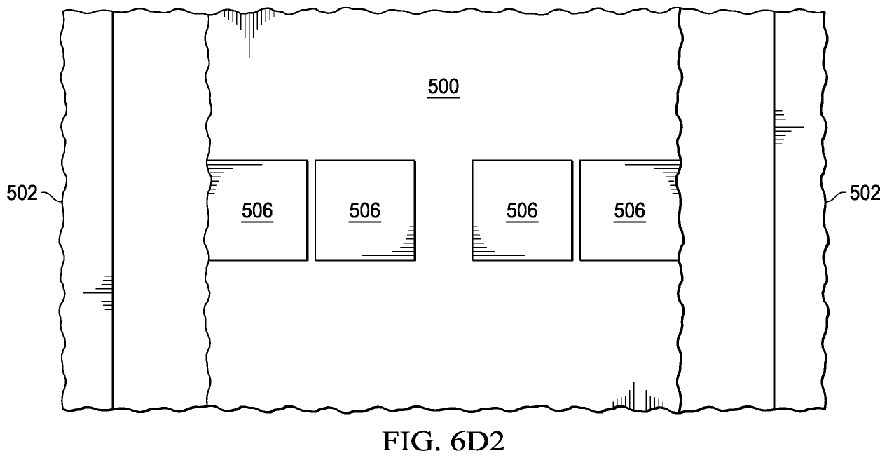

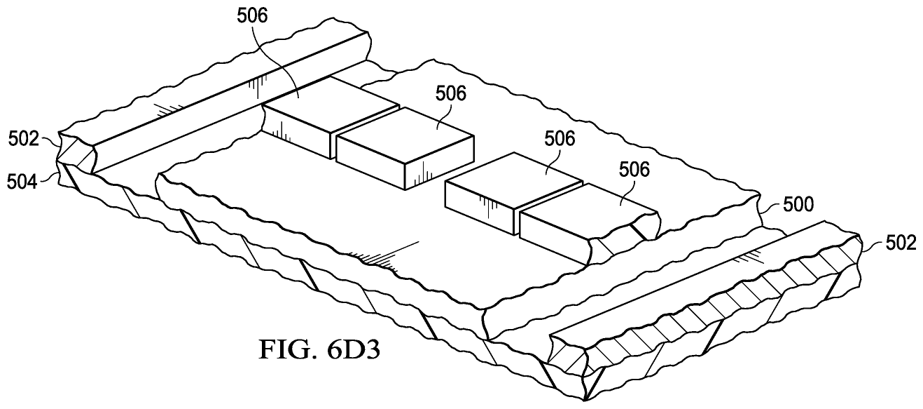

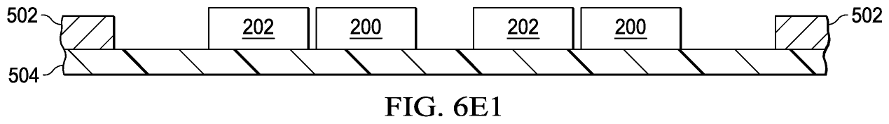

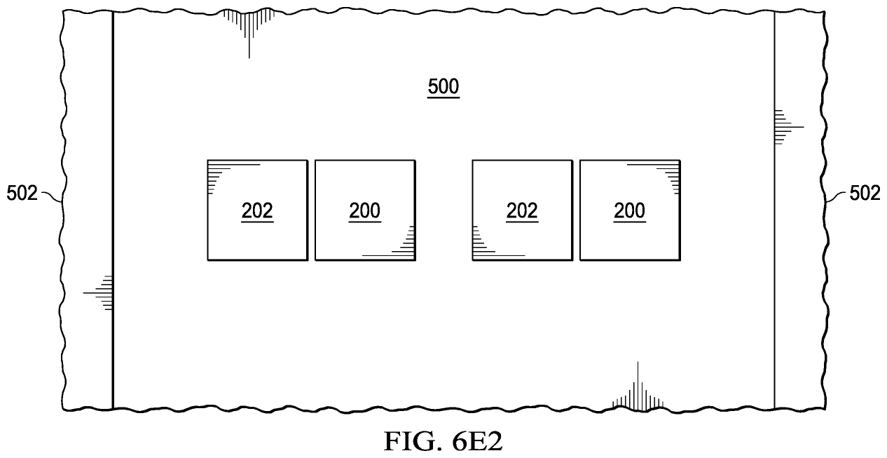

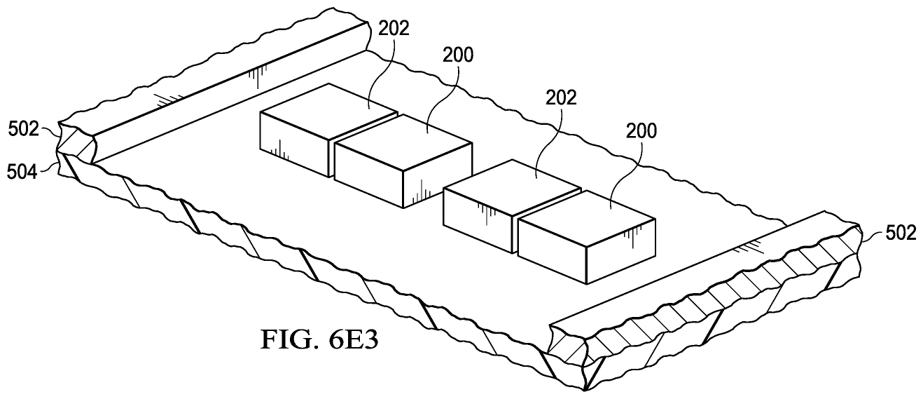

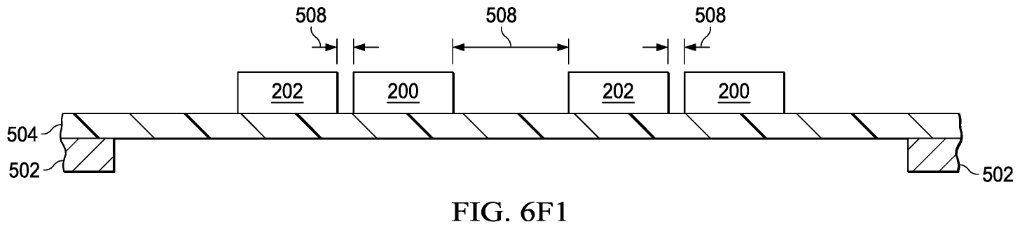

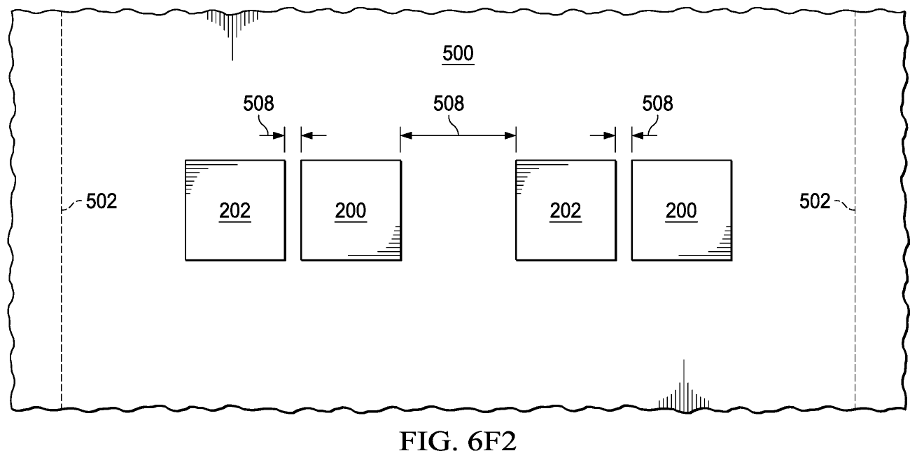

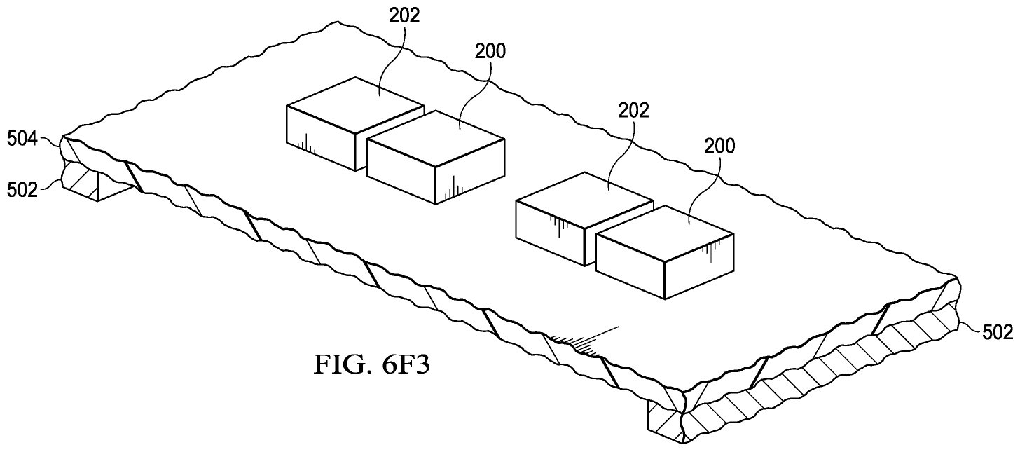

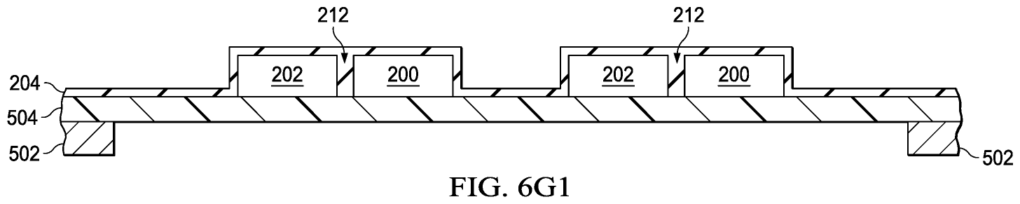

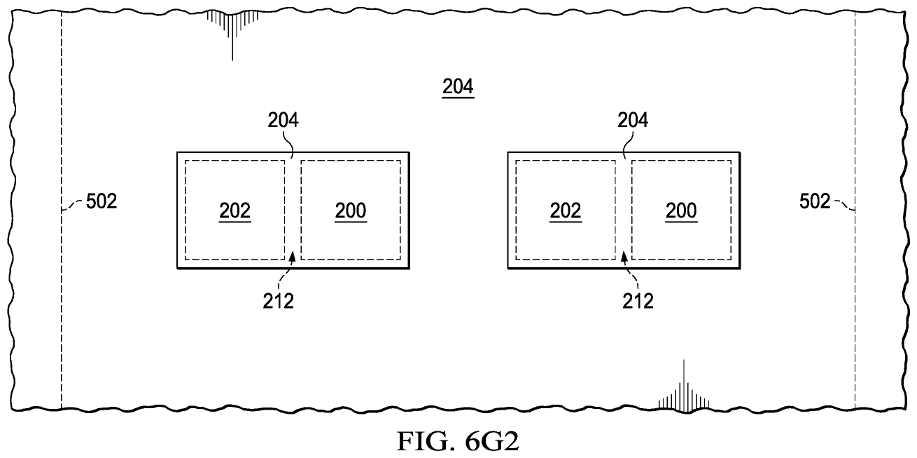

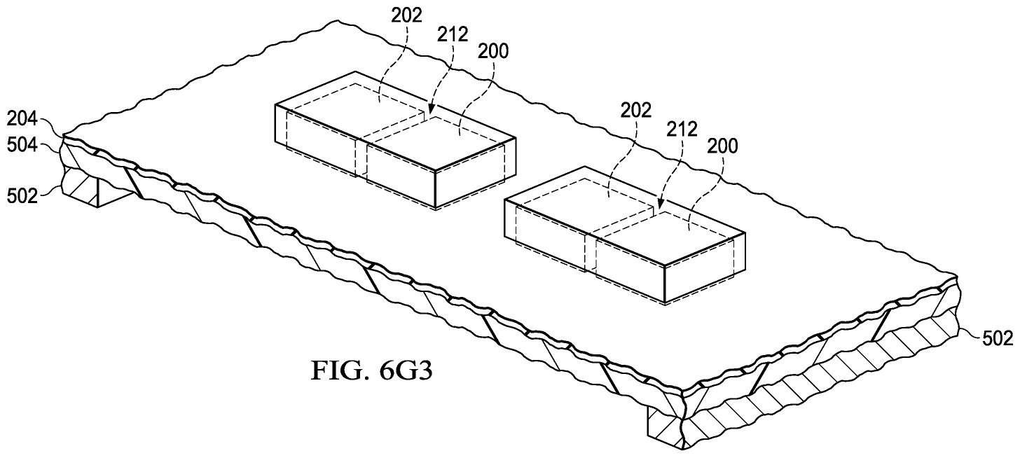

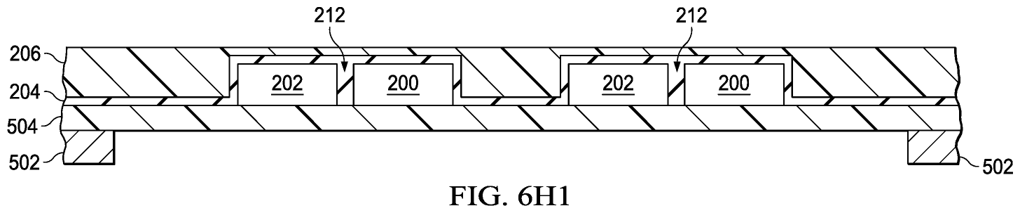

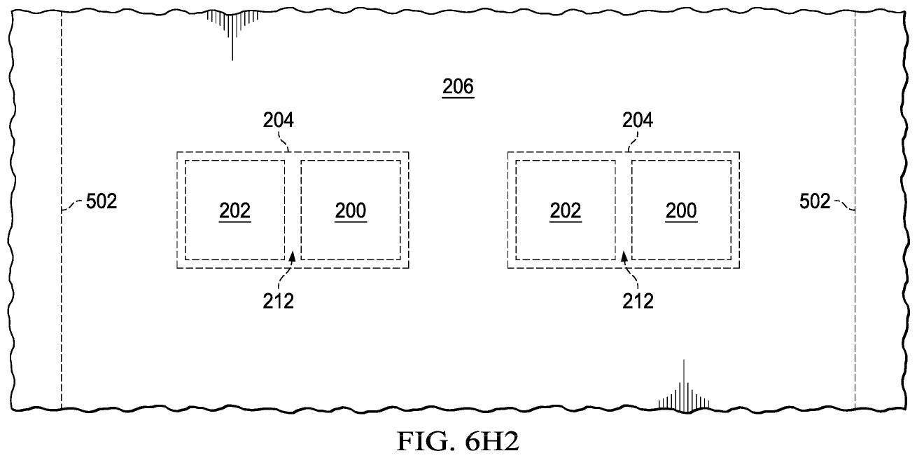

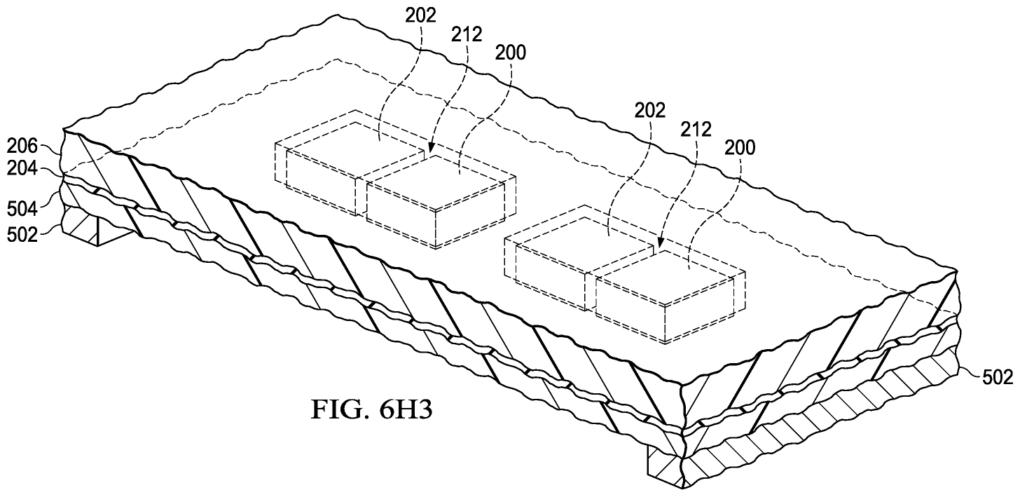

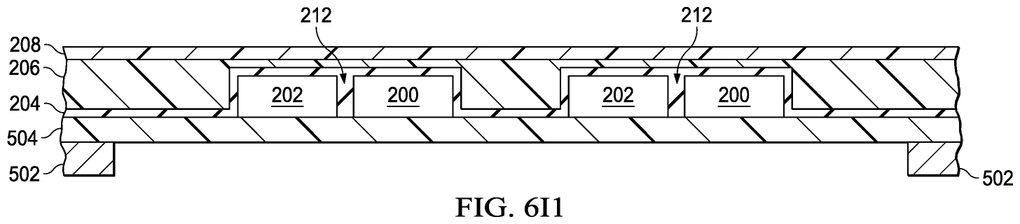

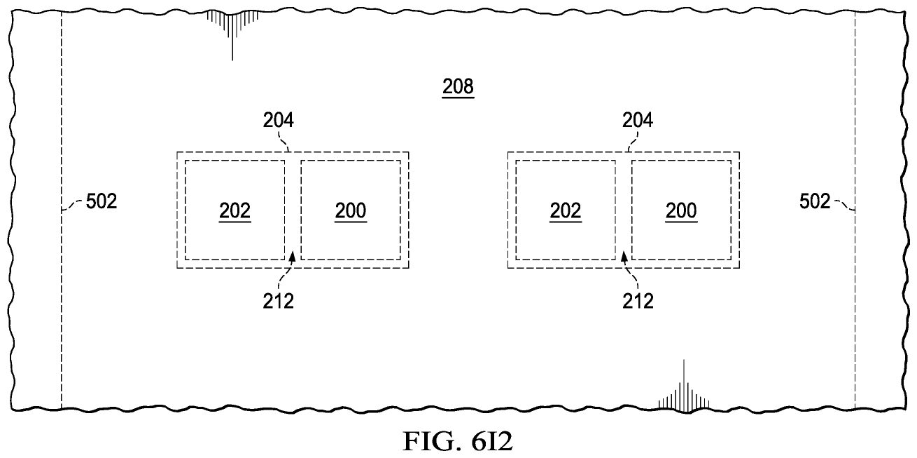

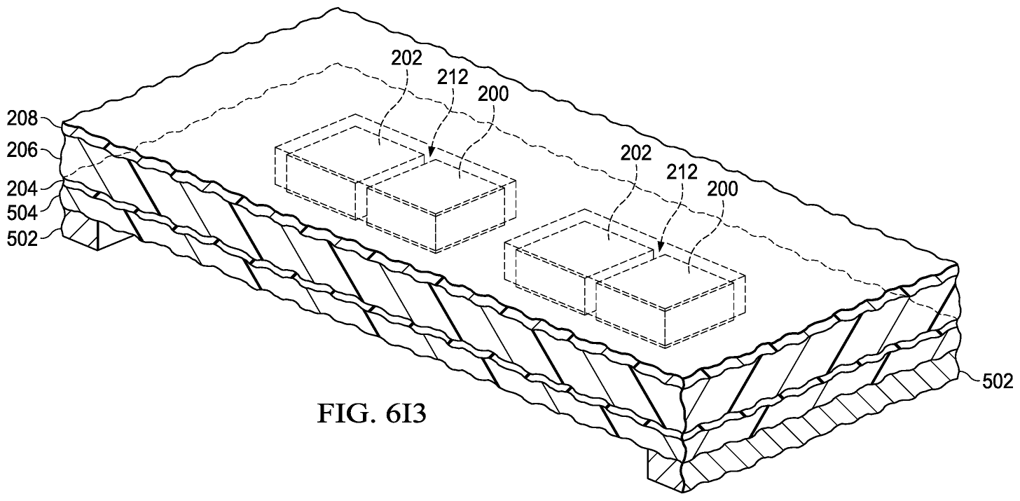

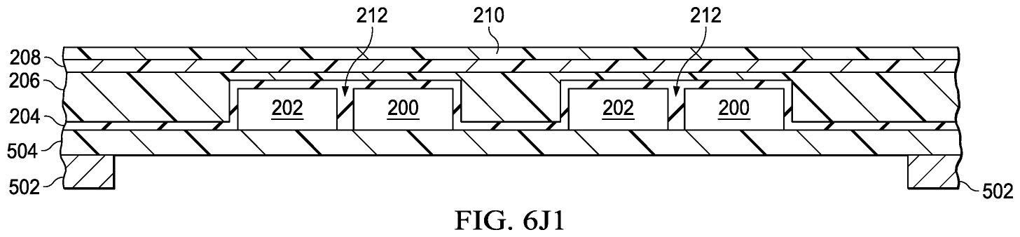

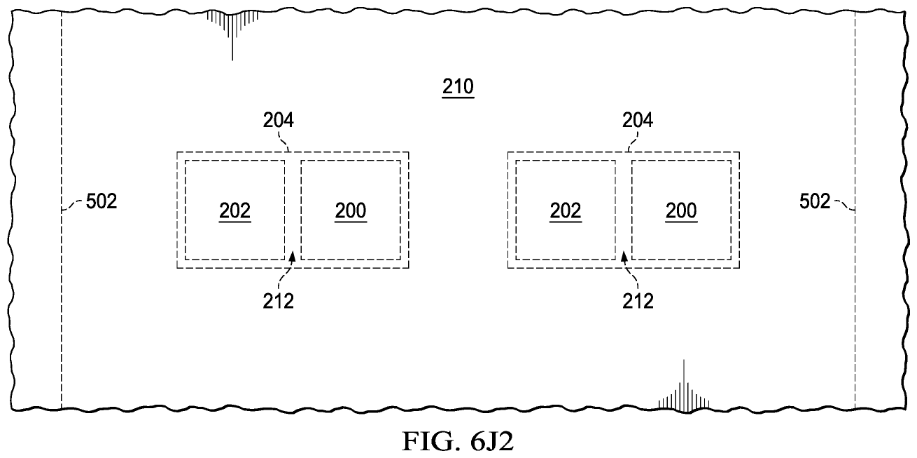

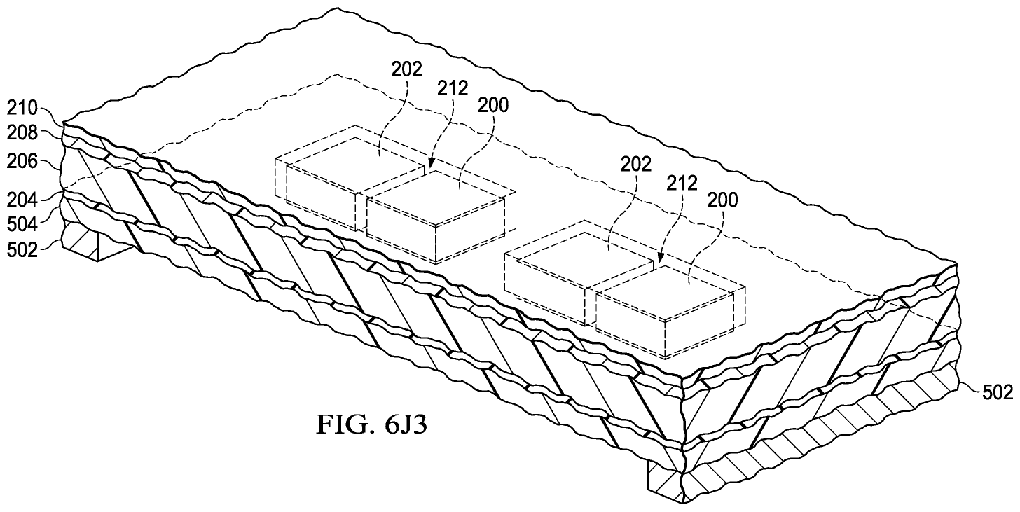

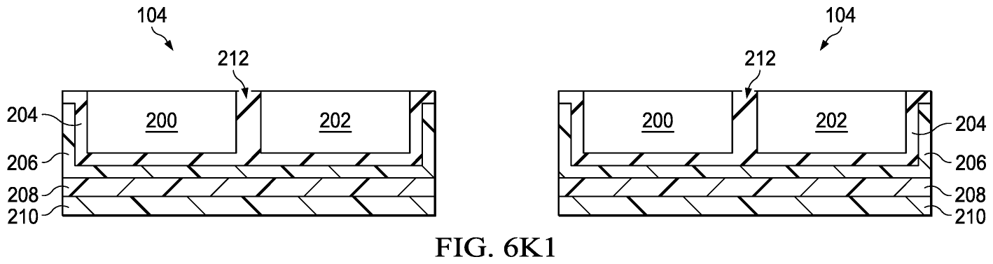

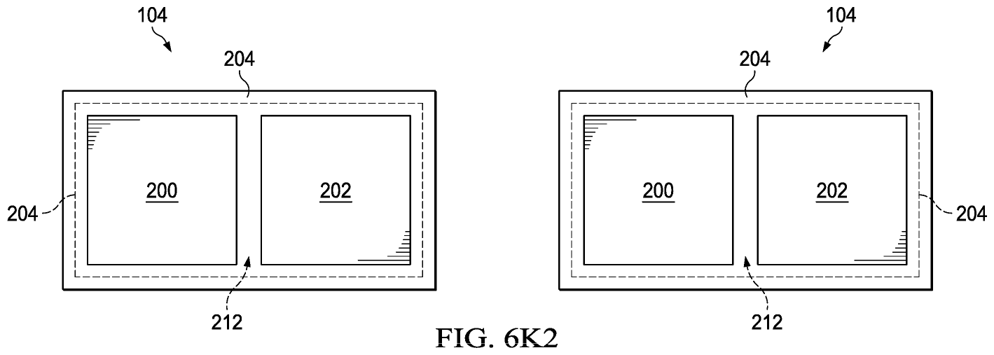

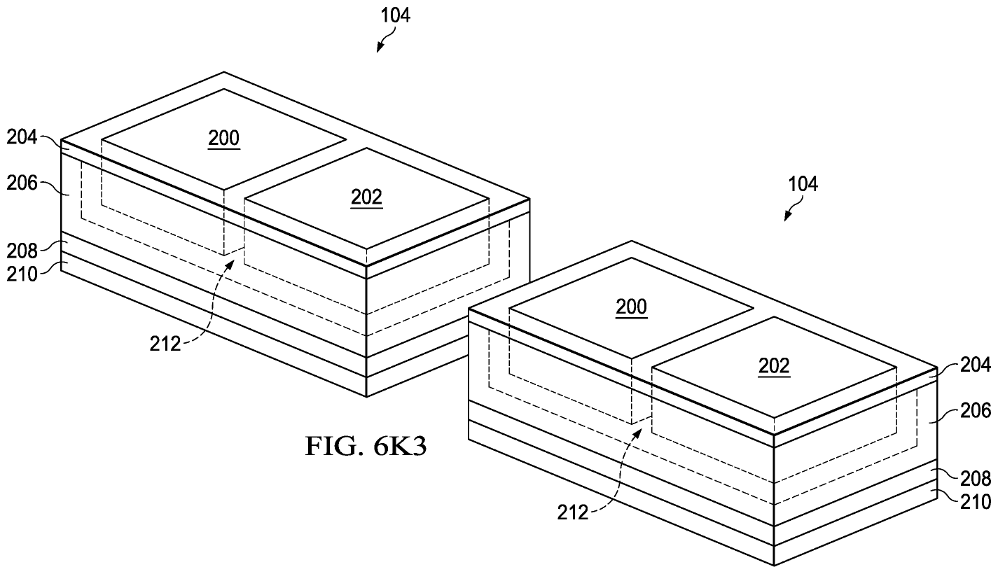

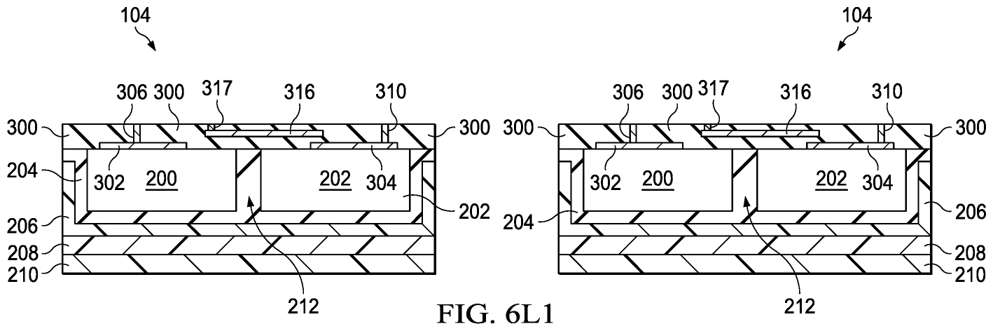

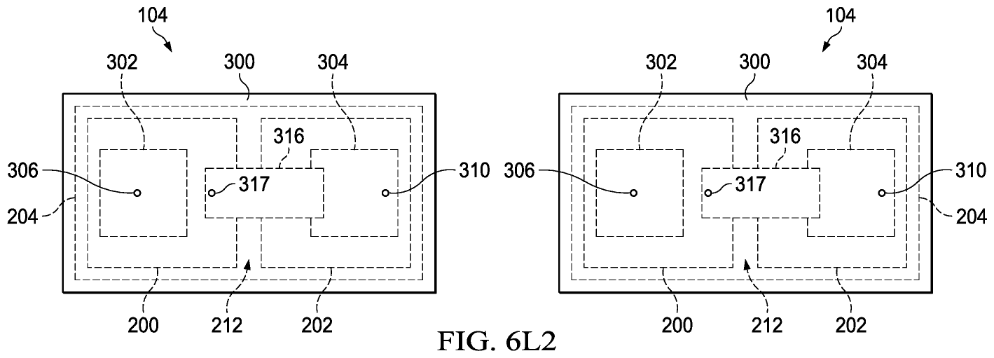

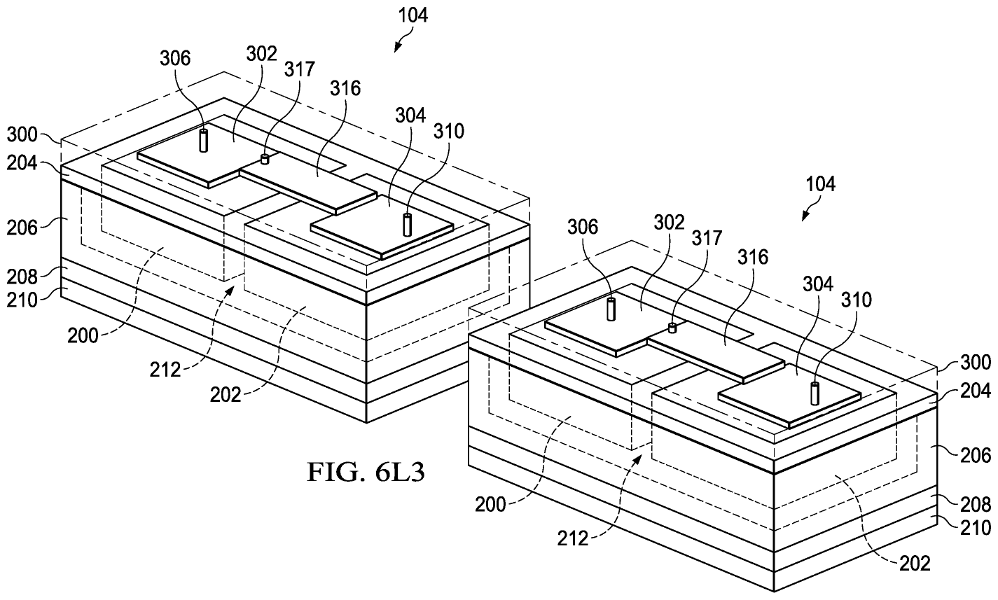

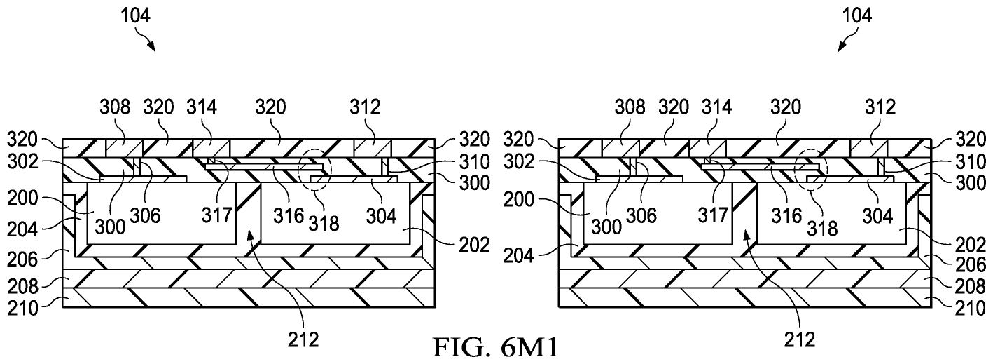

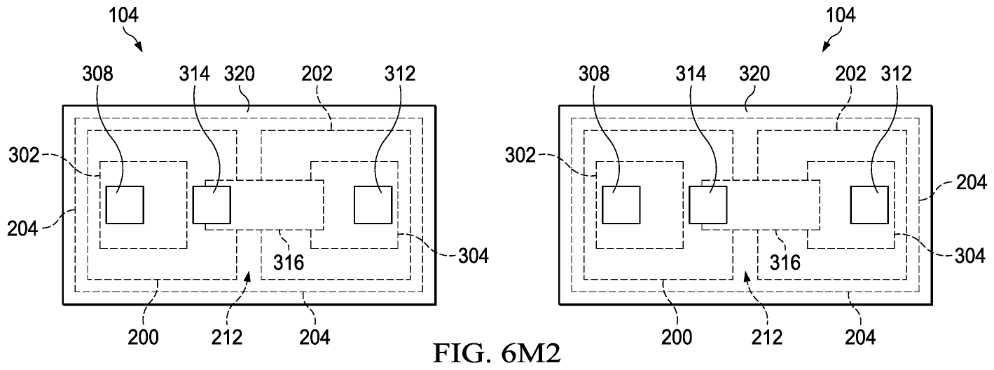

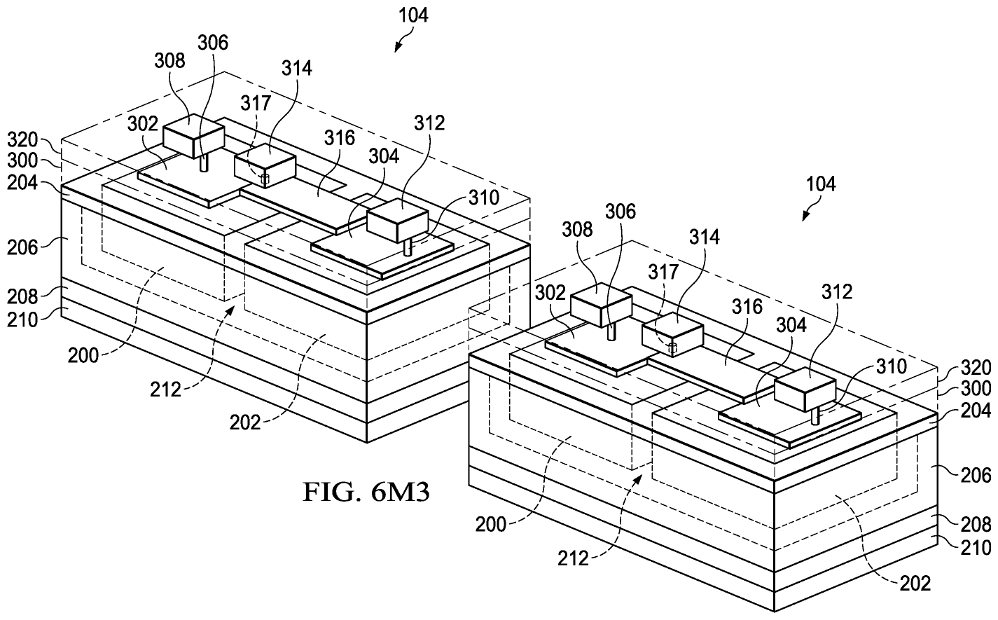

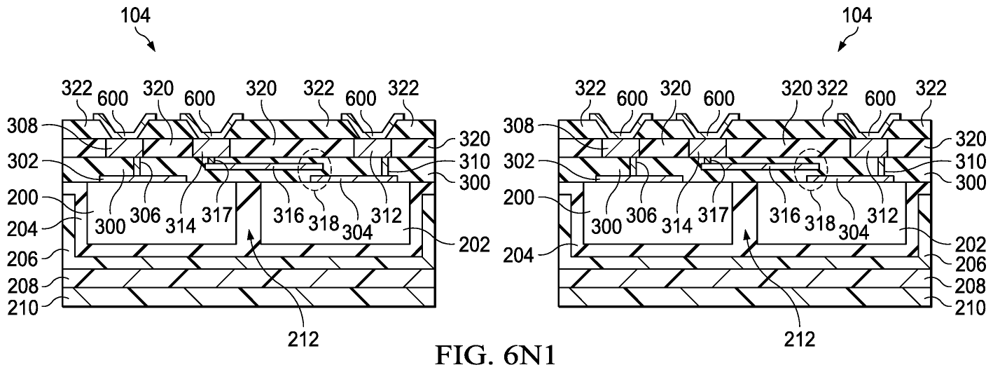

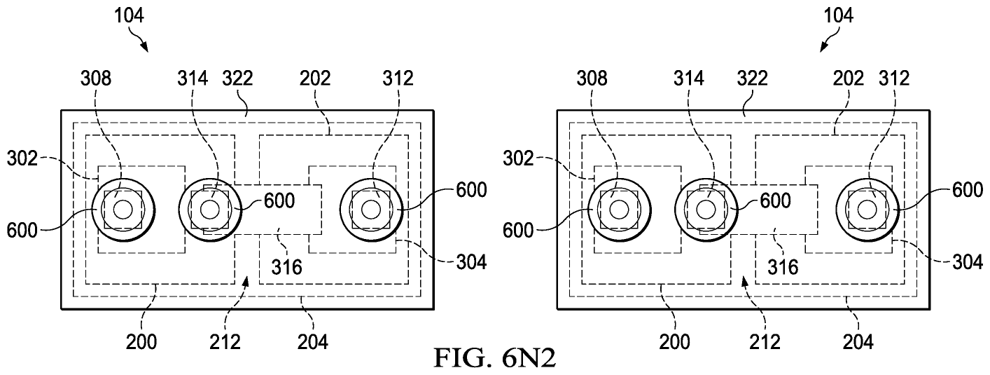

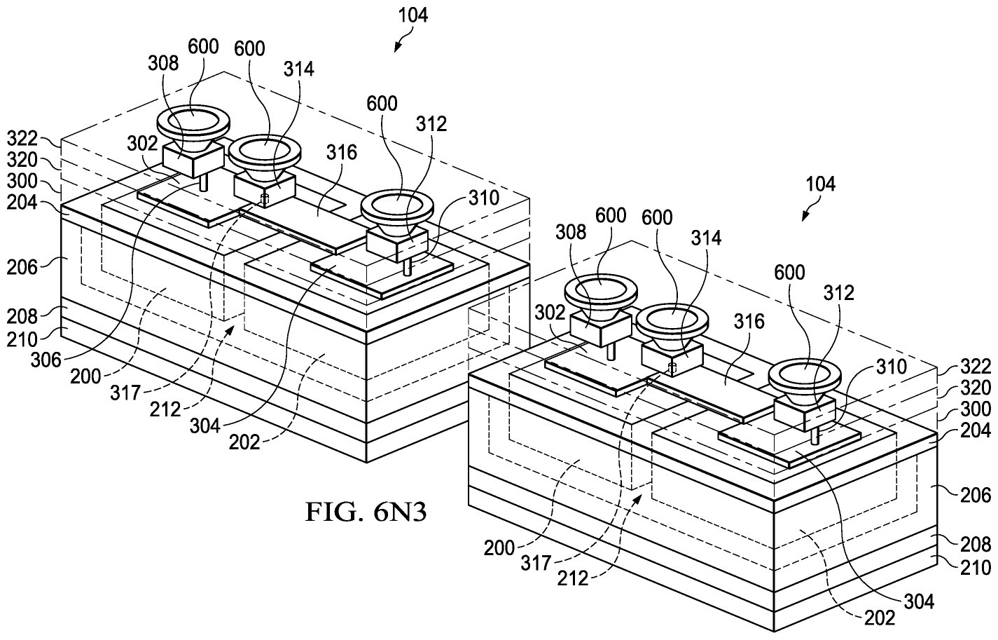

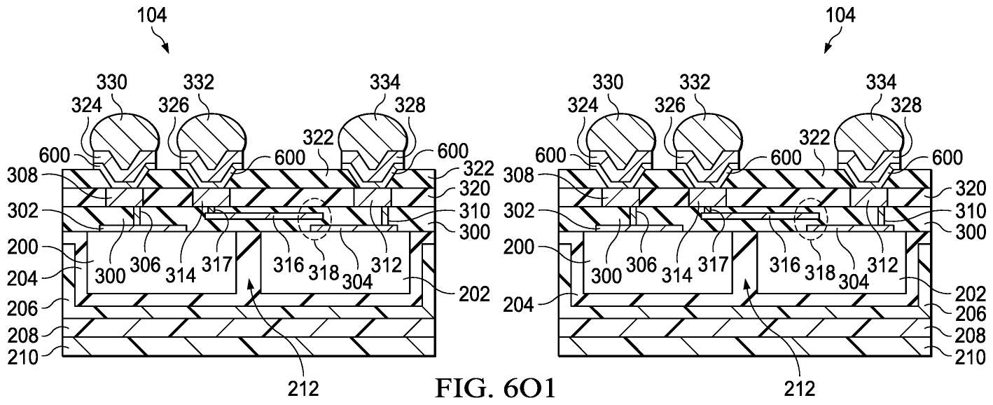

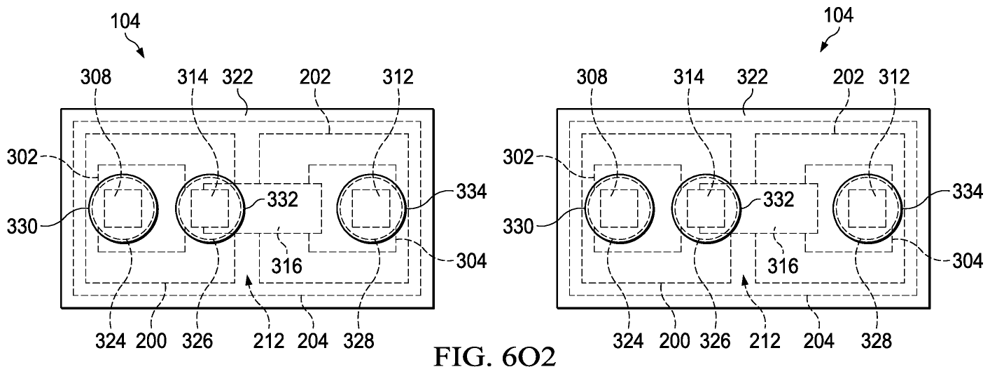

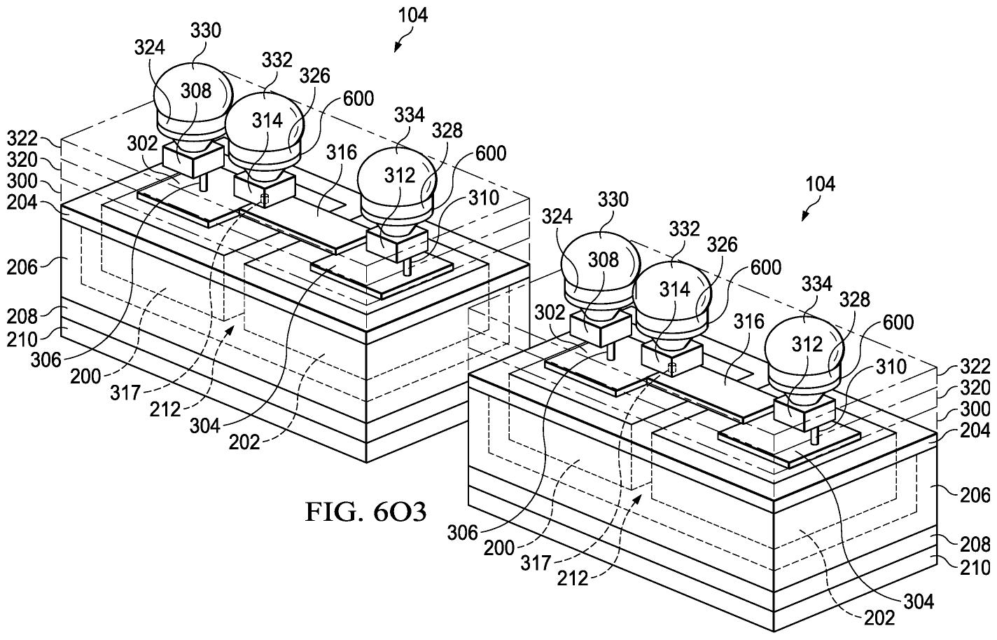

FIG. 4 is a flow diagram of a method 400 for manufacturing a package with isolated semiconductor dies (e.g., packages 104 of FIGS. 2A-2C and 3A-3C), in accordance with various examples. FIGS. 5A1-5O3 are a process flow for manufacturing a package with isolated semiconductor dies (e.g., package 104 of FIGS. 2A-2C), in accordance with various examples. FIGS. 6A1-6O3 are a process flow for manufacturing a package with isolated semiconductor dies (e.g., package 104 of FIGS. 3A-3C), in accordance with various examples. Accordingly, FIGS. 4, 5A1-5O3, and 6A1-6O3 are now described in parallel.

The method 400 includes backgrinding a semiconductor wafer (402). The wafer may include circuitry that is suitable for operating in differing voltage domains, and as described below, the portion of the wafer containing circuitry suitable for operating in a low voltage domain may be separated from the portion of the wafer containing circuitry suitable for operating in a high voltage domain. The wafer may include multiple portions of circuitry that are suitable for operating in low voltage domains and multiple portions of circuitry that are suitable for operating in high voltage domains. The method 400 also includes coupling the wafer to an expandable dicing tape (404). FIG. 5A1 is a profile, cross-sectional view of a wafer 500, and FIG. 5B1 is a profile, cross-sectional view of the wafer 500 having been backgrinded and coupled to an expandable dicing tape 504 coupled to a carrier 502. FIG. 5A2 is a top-down view of the structure of FIG. 5A1, in accordance with various examples. FIG. 5A3 is a perspective view of the structure of FIG. 5A1, in accordance with various examples. FIG. 5B2 is a top-down view of the structure of FIG. 5B1, in accordance with various examples. FIG. 5B3 is a perspective view of the structure of FIG. 5B1, in accordance with various examples.

The method 400 includes applying a photoresist to a non-device side of the wafer (406). FIG. 5C1 shows a profile, cross-sectional view of the structure of FIG. 5B1, except with a photoresist 506 coupled to the non-device side of the wafer 500. FIG. 5C2 is a top-down view of the structure of FIG. 5C1, in accordance with various examples. FIG. 5C3 is a perspective view of the structure of FIG. 5C1, in accordance with various examples.

The method 400 includes patterning the photoresist (408). FIG. 5D1 shows a profile, cross-sectional view of the structure of FIG. 5C1, except with the photoresist 506 patterned (e.g., using photolithographic techniques) so the structure of the photoresist 506 is suitable for etching the wafer 500 as desired. FIG. 5D2 is a top-down view of the structure of FIG. 5D1, in accordance with various examples. FIG. 5D3 is a perspective view of the structure of FIG. 5D1, in accordance with various examples.

The method 400 includes etching the wafer using the photoresist to produce multiple dies separated by gaps (410). FIG. 5E1 is a profile, cross-sectional view of the structure of FIG. 5D1, except with the wafer 500 etched (and, therefore, diced) to produce multiple dies 200 and multiple dies 202. The photoresist 506 is also removed. FIG. 5E2 is a top-down view of the structure of FIG. 5E1, in accordance with various examples. FIG. 5E3 is a perspective view of the structure of FIG. 5E1, in accordance with various examples.

The method 400 includes expanding the dicing tape to widen a gap between first and second groups of dies (412). FIG. 5F1 is a profile, cross-sectional view of the structure of FIG. 5E1, except that the dicing tape 504 has been stretched to widen gaps between the various dies 200, 202, as indicated by arrows 508. FIG. 5F2 is a top-down view of the structure of FIG. 5F1, in accordance with various examples. FIG. 5F3 is a perspective view of the structure of FIG. 5F1, in accordance with various examples.

The method 400 includes covering multiple surfaces of the dies with isolation material (414). FIG. 5G1 is a profile, cross-sectional view of the structure of FIG. 5F1, except with the addition of isolation material 204 covering the various dies 200, 202 and the exposed areas of the dicing tape 504. As shown, the isolation material 204 fills the gaps between the dies 200, 202, thus covering the lateral surfaces (e.g., four lateral surfaces) of each of the dies 200, 202. In addition, the isolation material 204 covers the surfaces of the dies 200, 202 most distal from the dicing tape 504. FIG. 5G2 is a top-down view of the structure of FIG. 5G1, in accordance with various examples. FIG. 5G3 is a perspective view of the structure of FIG. 5G1, in accordance with various examples.

The method 400 includes covering the isolation material with a first APP material (416). FIG. 5H1 is a profile, cross-sectional view of the structure of FIG. 5G1, except with the application of APP material 206 directly on the isolation material 204. The APP material 206 may be, for example, a resin material or polymer. The APP material 206 may be applied by any suitable technique, such as vacuum lamination, press lamination, spin-on, etc. FIG. 5H2 is a top-down view of the structure of FIG. 5H1, in accordance with various examples. FIG. 5H3 is a perspective view of the structure of FIG. 5H1, in accordance with various examples.

The method 400 includes covering the first APP material with a second APP material (418). FIG. 511 is a profile, cross-sectional view of the structure of FIG. 5H1, except with the addition of APP material 208 on the APP material 206. The APP material 208 may be, for example, a fiberglass material or epoxy. The APP material 208 may be applied by any suitable technique, such as vacuum lamination, press lamination, stencil print, etc. FIG. 512 is a top-down view of the structure of FIG. 511, in accordance with various examples. FIG. 513 is a perspective view of the structure of FIG. 511, in accordance with various examples.

The method 400 includes covering the second APP material with a third APP material (420). FIG. 5J1 is a profile, cross-sectional view of the structure of FIG. 511, except with the addition of APP material 210 on the APP material 208. The APP material 210 may be, for example, a resin material or polymer. The APP material 210 may be applied by any suitable technique, such as vacuum lamination, press lamination, spin-on, etc. FIG. 5J2 is a top-down view of the structure of FIG. 5J1, in accordance with various examples. FIG. 5J3 is a perspective view of the structure of FIG. 5J1, in accordance with various examples.

The method 400 includes performing a sawing process in the gap between the first and second groups of dies to produce individual packages (422) and removing the individual packages from the dicing tape (424). FIG. 5K1 is a profile, cross-sectional view of the structure of FIG. 5J1, except with the sawing operation having been performed in the gap between the innermost dies 200, 202 to produce individual (but incomplete) packages 104, and the dicing tape 504 and carrier 502 having been removed from the packages 104. FIG. 5K2 is a top-down view of the structure of FIG. 5K1, in accordance with various examples. FIG. 5K3 is a perspective view of the structure of FIG. 5K1, in accordance with various examples.

The method 400 includes applying passivation, polyimide, insulative, and/or metal layers to device sides of the packages (426). FIG. 5L1 is a profile, cross-sectional view of the structure of FIG. 5K1, except with the addition of metal contact pads 226, 230. The metal contact pads 226, 230 may be applied using any suitable technique, such as a plating technique, for example. FIG. 5L2 is a top-down view of the structure of FIG. 5L1, in accordance with various examples. FIG. 5L3 is a perspective view of the structure of FIG. 5L1, in accordance with various examples. FIG. 5M1 is a profile, cross-sectional view of the structure of FIG. 5L1, except with the application of passivation layer 224 on the metal contact pads 226, 230 and on the remainder of the top surfaces of the package 104 as shown. FIG. 5M2 is a top-down view of the structure of FIG. 5M1, in accordance with various examples. FIG. 5M3 is a perspective view of the structure of FIG. 5M2, in accordance with various examples.

FIG. 5N1 is a profile, cross-sectional view of the structure of FIG. 5M1, except that photolithographic and etching techniques have been used to form orifices in the passivation layer 224 in vertical alignment with the metal contact pads 226, 230, and these orifices are lined with seed layers 510 (e.g., copper seed layers). FIG. 5N2 is a top-down view of the structure of FIG. 5N1, in accordance with various examples. FIG. 5N3 is a perspective view of the structure of FIG. 5N1, in accordance with various examples. FIG. 5O1 is a profile, cross-sectional view of the structure of FIG. 5N1, except with the plating of UBMs 228, 232, and the deposition of solder bumps 234, 236 on the UBMs 228, 232, respectively. FIG. 5O2 is a top-down view of the structure of FIG. 5O1, in accordance with various examples. FIG. 5O3 is a perspective view of the structure of FIG. 5O1, in accordance with various examples. The package 104 of FIGS. 2A-2C is thus complete.

The steps 402-424 of method 400 may also be useful to manufacture the package 104 of FIGS. 3A-3C. The process flow of FIGS. 6A1-6K3 describes the manufacture of the package 104 of FIGS. 3A-3C according to steps 402-424 of method 400. The process flow of FIGS. 6A1-6K3 is identical to the process flow of FIGS. 5A1-5K3, respectively, and thus FIGS. 6A1-6K3 are not described again here. However, performance of the step 426 of method 400 differs when manufacturing package 104 of FIGS. 3A-3C relative to the manufacture of package 104 of FIGS. 2A-2C. Step 426 includes applying passivation, polyimide, insulative, and/or metal layers to device sides of the packages, and FIGS. 6L1-6O3 depict the performance of step 426. FIG. 6L1 is a profile, cross-sectional view of the structure of FIG. 6K1, except with the plating of vias 306, 310, and 317 and the metal layer 316, as well as the application of the oxide layer 300. The oxide layer 300 may be applied using any suitable technique, such as thermal oxide growth, chemical vapor deposition (CVD) oxide, etc. FIG. 6L2 is a top-down view of the structure of FIG. 6L1, in accordance with various examples. FIG. 6L3 is a perspective view of the structure of FIG. 6L1, in accordance with various examples. FIG. 6M1 is a profile, cross-sectional view of the structure of FIG. 6L1, except with the plating of metal contact pads 308, 312, and 314, and the application of the passivation layer 320. The passivation layer 320 may be applied using any suitable technique, such as thermal oxide growth, CVD oxide, etc. FIG. 6M2 is a top-down view of the structure of FIG. 6M1, in accordance with various examples. FIG. 6M3 is a perspective view of the structure of FIG. 6M1, in accordance with various examples.

FIG. 6N1 is a profile, cross-sectional view of the structure of FIG. 6M1, except with the application of polyimide layer 322, etching of the polyimide layer 322 above the metal contact pads 308, 312, and 314 to form orifices above the metal contact pads 308, 312, and 314, and lining of the orifices with seed layers 600 (e.g., copper seed layers). FIG. 6N2 is a top-down view of the structure of FIG. 6N1, in accordance with various examples. FIG. 6N3 is a perspective view of the structure of FIG. 6N1, in accordance with various examples. FIG. 6O1 is a profile, cross-sectional view of the structure of FIG. 6N1, except with the plating of UBMs 324, 326, and 328 and the deposition of solder bumps 330, 332, and 334 on the UBMs 324, 326, and 328, respectively. FIG. 6O2 is a top-down view of the structure of FIG. 6O1, in accordance with various examples. FIG. 6O3 is a perspective view of the structure of FIG. 6O1, in accordance with various examples. The package 104 of FIGS. 3A-3C is thus complete.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A wafer chip scale package (WCSP), comprising:
first and second dies in differing voltage domains;
an isolation material between the first and second dies and contacting multiple surfaces of each of the first and second dies;
a first resin material contacting multiple surfaces of the isolation material, the isolation material between the resin material and the first and second dies;
a fiberglass material contacting a surface of the resin material;
a second resin material contacting a surface of the fiberglass material;
first and second conductive structures coupled to the first and second dies, respectively; and
a passivation material contacting the first and second dies and the first and second conductive structures.

2. The WCSP of claim 1, wherein a portion of the isolation material between the first and second dies has a thickness ranging from 2 microns to 50 microns.

3. The WCSP of claim 1, wherein at least one of the first and second resin materials and the fiberglass material are asymmetric pre-preg (APP) materials.

4. The WCSP of claim 1, wherein the first resin material has a thickness ranging from 10 microns to 200 microns, the second resin material has a thickness ranging from 10 microns to 150 microns, and the fiberglass material has a thickness ranging from 10 microns to 100 microns.

5. The WCSP of claim 1, wherein the isolation material comprises parylene.

6. A wafer chip scale package (WCSP), comprising:
a first die having a first top surface, a first bottom surface opposing the first top surface, and multiple first lateral surfaces;
a second die having a second top surface, a second bottom surface opposing the second top surface, and multiple second lateral surfaces, the first and second dies in differing voltage domains;
an isolation material contacting the first and second bottom surfaces, the multiple first lateral surfaces, and the multiple second lateral surfaces, a portion of the isolation material between the first and second dies having a width ranging from 2 microns to 50 microns; and
an asymmetric pre-preg (APP) material contacting the isolation material and having a tensile modulus ranging from 1 gigapascals (GPa) to 30 GPa.

7. The WCSP of claim 6, wherein the isolation material comprises parylene.

8. The WCSP of claim 6, wherein the APP material comprises a fiberglass-based asymmetric pre-preg (APP) material and has a thickness ranging from 10 microns to 100 microns.

9. The WCSP of claim 6, further comprising:
a first resin-based APP material contacting the APP material and having a thickness ranging from 10 microns to 200 microns; and
a second resin-based APP material contacting the APP material and having a thickness ranging from 10 microns to 150 microns.

10. A method for manufacturing a wafer chip scale package (WCSP), comprising:
backgrinding a semiconductor wafer;
coupling the wafer to an expandable dicing tape;
patterning a photoresist on a non-device side of the wafer;
etching the wafer using the photoresist to produce first and second dies separated by a gap;
filling the gap with an isolation material;
covering multiple surfaces of the first and second dies with the isolation material; and
performing a sawing process to produce a WCSP including the first and second dies.

11. The method of claim 10, wherein the isolation material has a width ranging from 2 microns to 50 microns.

12. The method of claim 10, further comprising:
expanding the dicing tape to form a second gap between a first group of dies and a second group of dies, the first group of dies including the first and second dies,
wherein the sawing process is performed in the second gap between the first and second groups of dies.

13. The method of claim 10, further comprising covering the isolation material with a first resin material.

14. The method of claim 13, wherein the first resin material has a thickness ranging from 10 microns to 200 microns.

15. The method of claim 13, further comprising covering the first resin material with a fiberglass material.

16. The method of claim 15, wherein the fiberglass material has a thickness ranging from 10 microns to 100 microns.

17. The method of claim 15, further comprising covering the fiberglass material with a second resin material.

18. The method of claim 17, wherein the second resin material has a thickness ranging from 10 microns to 150 microns.

19. The method of claim 10, further comprising plating a metal contact pad on the first die.

20. The method of claim 19, further comprising at least partially covering the metal contact pad with a polyimide layer, applying a seed layer on the polyimide layer, plating the seed layer to form an under bump metallization, and depositing a solder bump on the under bump metallization.

21. The method of claim 10, wherein the first and second dies are in differing voltage domains.
